(19) United States
(12) Patent Application Publication
(10) Pub. No.: US 2026/0344069 A1
(43) Pub. Date: Oct. 29, 2026

(54) ENHANCED METAL-INSULATOR-METAL DIODES IN TERAHERTZ COMMUNICATION SYSTEMS

(71) Applicants: Dogu Kaan Bugra OZYIGIT, Toronto (CA); Bersu BASTUG AZER, Waterloo (CA); Ahmet GULSARAN, Waterloo (CA); George SHAKER, Waterloo (CA); Mustafa YAVUZ, Waterloo (CA); Michal BAJCSY, Waterloo (CA)

(72) Inventors: Dogu Kaan Bugra OZYIGIT, Toronto (CA); Bersu BASTUG AZER, Waterloo (CA); Ahmet GULSARAN, Waterloo (CA); George SHAKER, Waterloo (CA); Mustafa YAVUZ, Waterloo (CA); Michal BAJCSY, Waterloo (CA)

(21) Appl. No.: 19/391,281

(22) Filed: Nov. 17, 2025

Related U.S. Application Data
(60) Provisional application No. 63/722,350, filed on Nov. 19, 2024.

(51) Int. Cl. H10F 30/295

(52) U.S. Cl. CPC H10F 30/295

(57) ABSTRACT

Metal-insulator-metal (MIM) diodes based on black titanium dioxide are fabricated by in situ hydrogen doping via plasma assisted atomic layer deposition (PAALD). Hydrogen doped Pt/H—TiOₓ/Al diodes with varying hydrogenation times are fabricated with a novel process. The hydrogen produce oxygen vacancies and modify the bandgap of TiO₂, therefore changing the conduction mechanisms of the diodes. This leads to enhanced electron transport and improved performance of the hydrogen-doped diodes. Dual layer metal-insulator-insulator-metal (MIIM) diodes having a layer of TiO₂ with another layer of N—Al₂O₃ or N—TiO₂ are shown to have further improved characteristics. This defect-engineering approach is found to reduce diode resistance without negatively impacting the figure of merit.

### CROSS REFERENCE TO RELATED APPLICATIONS

This application claims the benefit of priority of U.S. Provisional Patent Application No. 63/722,350 filed Nov. 19, 2024, which is hereby incorporated by reference.

### FIELD

The present disclosure relates generally to Metal-Insulator-Metal (MIM) diodes. More particularly, the present disclosure relates to the insulator of MIM diodes.

### BACKGROUND

The projected increase in wireless data traffic for the upcoming decade is encouraging both academia and industry to think beyond current wireless technologies and consider the potential of sixth-generation (6G) wireless networks. Among a range of advanced and promising solutions, terahertz (THz) communications, which operate within the ultra-wide THz band from 0.1 to 10 THz, are seen as highly promising for the 6G era and beyond. This is due to their unique capability of supporting terabit-per-second transmission in emerging applications.

This advancement has consequently led to the development of affordable, scalable methods for manufacturing THz devices. Metal-Insulator-Metal (MIM) diodes are one of the promising candidates for THz applications. These unique diodes, which feature a thin insulating layer sandwiched between two metal contacts, employ a quantum-tunnelling electron transport mechanism, making them well-suited for high-frequency signal rectification. Their primary applications include solar rectennas, infrared detectors, and wireless power transmission systems.

MIM diodes play a crucial role in the rapidly advancing field of THz technology. The performance of these diodes heavily relies on the quality of the insulating layer. Traditional oxidation techniques, including native, thermal, plasma, and anodic oxidation, are used to grow an oxide layer over the base metal electrodes such as Ni, Ti, and Al.

However, achieving consistent oxide quality and thickness using these methods poses challenges due to varying conditions of humidity and partial pressure of oxygen in the air. In contrast, a more promising approach known as in situ oxidation offers controlled results and lower defect density. The limitations of oxidation methods lie in their ability to produce only derivative oxides of the base metal. To overcome this constraint, deposition techniques such as sputtering, electron beam evaporation, pulsed laser deposition, and Atomic Layer Deposition (ALD) have been developed. Among these, ALD stands out as it produces high-quality oxides with low defect density and excellent conformality, making it suitable for insulator deposition in MIM fabrication. However, their usage is mostly limited by slow deposition rates and the requirement for a vacuum environment.

These limitations hinder the scalability of MIM diode production, a critical aspect of their integration into the growing THz field.

Other alternate types of diodes have been developed, such as Schottky diodes, which have been used extensively in the millimeter-wave frequency range. While Schottky diodes can indeed operate at THz frequencies, their performance decreases significantly in this range due to the high parasitic capacitance and resistance associated with the diode junction.

Other techniques, such as Quantum Cascade Lasers (QCLs) and Impatt diodes, have also been studied for their potential use in THz communication systems. QCLs, for instance, have been shown to be effective sources of THz radiation. However, they require cryogenic cooling to function, making them impractical for most communication systems. On the other hand, Impatt diodes can operate at THz frequencies, but they are known for their high noise levels, which can negatively impact the signal quality in a communication system.

Another area of research has been the use of graphene-based devices for THz communication. Graphene has been shown to have remarkable properties at THz frequencies, such as tunable conductivity, which could be beneficial for THz communication systems. However, the technology is still in its infancy and has yet to prove its practical applicability.

Despite these attempts, each of these technologies comes with inherent disadvantages. They either suffer from poor performance at THz frequencies, high levels of noise, impractical operating requirements, or they are still in the early stages of development with much left to be proven. Furthermore, none of these technologies have adequately addressed the issue of low conversion efficiency when operating at THz frequencies, which is a challenge for the practical implementation of THz communication systems.

In light of these limitations, the use of MIM diodes in THz communication systems remains a promising area of exploration. With their ability to operate at extremely high frequencies and their non-linear characteristics that enable efficient rectification and modulation of THz waves, MIM diodes offer potential solutions to the challenges of THz communications.

Furthermore, the performance of the MIM diode should be optimized for the terahertz spectrum for communication. This frequency range offers vast potential for high-speed data transfer but poses significant technical hurdles.

Here the insulator component should enable high responsivity while maintaining low resistance. Traditional insulators have fallen short in this regard.

Signal attenuation in the terahertz range is another problematic issue with currently known MIM diodes. Terahertz waves suffer substantial signal loss, especially over longer distances.

It is, therefore, desirable to at least:
1. engineer an insulator with defects that enhance electron tunneling at terahertz frequencies;
2. achieve high responsivity and low resistance simultaneously in the MIM diode;
3. mitigate signal attenuation in terahertz communication; and
4. develop a complete terahertz communication system capable of efficient data transmission and reception.

### SUMMARY

It is an object of the present disclosure to obviate or mitigate at least one disadvantage of previous MIM diodes and methods of fabricating them.

In a first aspect, the present disclosure provides a metal-insulator-metal diode. The metal-insulator-metal diode includes a first metal electrode, a second metal electrode and at least one insulating layer. The first metal electrode has a corresponding work function. The second metal electrode has a corresponding work function, where the first and the second metal electrode work function difference is at least 0 eV. The at least one insulating layer is doped and ion implanted to form intrinsic defects enhancing charge carrier mobility, and is in electrical communication with the first metal electrode and the second metal electrode to enable THz frequency operations between the first metal electrode and the second metal electrode.

In an embodiment of the first aspect, the first metal electrode is selected from the group consisting of titanium (Ti), platinum (Pt), nickel (Ni), niobium (Nb), aluminum (Al), chromium (Cr), gold (Au), silver (Ag), copper (Cu), and tantalum (Ta). In this embodiment, the second metal electrode is selected from the same group, with the first and second metal electrode work function difference being at least 0-2 eV.

In further embodiments of the present aspect, the at least one insulating layer is selected from the group consisting of titanium dioxide (TiO₂), niobium pentoxide (Nb₂O₅), zinc oxide (ZnO), aluminum oxide (Al₂O₃), hafnium oxide (HfO₂), tantalum pentoxide (Ta₂O₅), cobalt oxide (Co₃O₄), nickel oxide (NiO), copper oxide (CuO), silicon dioxide (SiO₂), chromium oxide (Cr₂O₃), and vanadium pentoxide (V₂O₅). In this further embodiment, the at least one insulating layer is a single layer having a thickness of about 0.1-10 nm, or the at least one insulating layer includes at least two layers having a total thickness of about 0.1-100 nm, or the at least one insulating layer includes a first layer selected from the same group and a second layer selected from the same group, or each of the at least one insulating layer is doped with nitrogen and ion implanted with hydrogen or treated with hydrogen, oxygen, nitrogen, or argon plasma to form the intrinsic defects.

According to an alternate embodiment, the first metal electrode is platinum (Pt), the second metal electrode is aluminum (Al) and the at least one insulating layer includes a primary layer of H—TiO₂ adjacent the first metal electrode. In this embodiment, the at least one insulating layer can include a secondary nitrogen doped insulating layer between the second metal electrode and the primary layer of H—TiO₂. The secondary nitrogen doped insulating layer can be N—Al₂O₃ between the second metal electrode and the primary layer of H—TiO₂, or the secondary nitrogen doped insulating layer can be N—TiO₂ between the second metal electrode and the primary layer of H—TiO₂.

In a second aspect, the present disclosure provides a process for fabricating a metal-insulator-metal diode. The method includes depositing a first metal electrode having a corresponding work function; growing at least one oxide insulating film on the first metal electrode at a temperature of at least 100 degrees Celsius in the presence of a gas to form intrinsic defects enhancing charge carrier mobility, to a thickness of at least 0.1 nm; and depositing a second metal electrode having a corresponding work function over the at least one oxide insulating film, the first and the second metal electrode work function difference being at least 0 eV and being in electrical communication with each other via the at least one oxide insulating film.

According to an embodiment of the second aspect, the first electrode includes any one of sputtering, vacuum evaporation, electron-beam deposition, chemical vapor deposition (CVD), and atomic layer deposition (ALD) of elements selected from the group consisting of titanium (Ti), platinum (Pt), nickel (Ni), niobium (Nb), aluminum (Al), chromium (Cr), gold (Au), silver (Ag), copper (Cu), and tantalum (Ta).

According to another embodiment of the second aspect, growing the at least one oxide insulating film includes setting a voltage range of 50-1000 V and/or a temperature of 50-500 °C, under atmospheric pressure or in a vacuum environment ranging from 760 Torr to 10⁻¹² Torr.

In yet further embodiments of the present aspect, the at least one oxide insulating film is selected from the group consisting of titanium dioxide (TiO₂), niobium pentoxide (Nb₂O₅), zinc oxide (ZnO), aluminum oxide (Al₂O₃), hafnium oxide (HfO₂), tantalum pentoxide (Ta₂O₅), cobalt oxide (Co₃O₄), nickel oxide (NiO), copper oxide (CuO), silicon dioxide (SiO₂), chromium oxide (Cr₂O₃), and vanadium pentoxide (V₂O₅), or growing the at least one oxide insulating film includes growing a single layer of film having a thickness of 0.1-10 nm, or multiple layers of film having a total thickness of 0.1-100 nm, or growing the at least one oxide insulating film includes doping with nitrogen and either ion implanted with hydrogen, treated in situ or after deposition with hydrogen, oxygen, nitrogen, or argon plasma, or both, with at least three of these treatments or all of them.

In another embodiment of the second aspect, depositing the second metal electrode includes any one of sputtering, vacuum evaporation, electron-beam deposition, CVD, or ALD, of elements selected from the group consisting of titanium (Ti), platinum (Pt), nickel (Ni), niobium (Nb), aluminum (Al), chromium (Cr), gold (Au), silver (Ag), copper (Cu), and tantalum (Ta), with the work function difference between the first and second metal electrodes being at least 0.1-2 eV.

Other aspects and features of the present disclosure will become apparent to those ordinarily skilled in the art upon review of the following description of specific embodiments in conjunction with the accompanying figures.

### BRIEF DESCRIPTION OF THE DRAWINGS

Embodiments of the present disclosure will now be described, by way of example only, with reference to the attached Figures.

FIG. 1a is a schematic illustration of cross-sectional view of the Pt—Al₂O₃—Al MIM diode device architecture after deposition of the top Al electrode and patterning steps, according to a present embodiment;

FIG. 1b is a scanning electron microscopy (SEM) image of a fabricated MIM diode of the present embodiments, having a contact area of 0.002 μm²;

FIG. 2a is a 3D Atomic force microscope image of 9 nm Al₂O₃ by PEALD;

FIG. 2b is a 3D Atomic force microscope image of 9 nm Al₂O₃ by AP-CVD;

FIG. 3a is an energy diagram of the Pt— Al₂O₃—Al MIM diode of the present embodiments;

FIG. 3b is a representation of Schottky Emission, Fowler-Nordheim Tunneling, Poole-Frenkel Emission, Direct tunneling conduction mechanisms in asymmetric positive biased MIM diode;

FIG. 4a is a plot showing XPS spectra of Al₂O₃ films—O 1 s: AP-CVD;

FIG. 4b is a plot showing XPS spectra of Al₂O₃ films—O 1 s: PEALD;

FIG. 4c is a plot showing XPS spectra of Al₂O₃ films—Al 2p;

FIG. 5a is a plot showing the relationship between responsivity and resistance for AP-CVD diodes across varying insulator thicknesses (3 nm, 6 nm, and 9 nm) at 0.60 V bias;

FIG. 5b is a plot showing the relationship between responsivity and resistance for PEALD diodes across varying insulator thicknesses (3 nm, 6 nm, and 9 nm) at 0.60 V bias;

FIG. 6a is a plot showing I-V data for diodes made with AP-CVD operating under the Poole-Frenkel conduction mode;

FIG. 6b is a plot showing I-V data for diodes made with made with AP-CVD operating under the Schottkey emission conduction mode;

FIG. 6c is a plot showing I-V data for diodes made with PEALD operating under the Poole-Frenkel conduction mode;

FIG. 6d is a plot showing I-V data for diodes made with made with PEALD operating under the Schottkey emission conduction mode;

FIG. 7 is a plot showing refractive indices of Al₂O₃ measured by ellipsometry for AP-CVD and PEALD films;

FIG. 8a-c are plots of I-V Curves of AP-CVD and PEALD diodes with 3 nm, 6 nm, and 9 nm thicknesses;

FIG. 9a is a diagram of the device architecture of a Pt/TiO₂/Al MIM diode;

FIG. 9b is a diagram of the device architecture of a Pt/N-TiOₓ/Al MIM diode;

FIG. 9c is a diagram of the device architecture of a Pt/H—TiOₓ/Al MIM diode, according to a present embodiment;

FIG. 9d shows SEM images (370× and 4000×) of a Pt/H—TiOₓ/Al diode with 80 μm² area;

FIGS. 10a to 10f are plots showing optical coefficients and absorption spectra of various TiOₓ films;

FIG. 11a is a Tauc plot for TiO₂, N—TiOₓ and H—TiOₓ (6 s) films;

FIG. 11b is a Tauc plot for H—TiOₓ (1 s), H—TiOₓ (3 s) and H—TiOₓ (6 s) films;

FIG. 11c is a plot showing Ti 2p XPS spectra;

FIG. 11d is a plot showing high resolution valance band XPS spectra;

FIG. 11e is a plot showing the density of states (DOS) for various films;

FIG. 12a shows an electrical characterization resistance plot of MIM diodes with respect to the hydrogenation time;

FIG. 12b shows an electrical characterization resistance plot of MIM diodes with respect to type of dopant;

FIG. 12c shows an electrical characterization resistance plot of MIM diodes with respect to overlap area;

FIG. 12d is a plot of responsivity vs. resistance for H—TiOₓ diodes, where the overlap area of diodes in FIGS. 12a and 12b are 80 μm²;

FIG. 13 is a modeled cutoff frequency plot with respect to diode resistance;

FIG. 14a is an XPS survey spectra for TiOₓ films;

FIG. 14b shows the O1 s spectra for the TiOₓ films;

FIG. 14c shows the N 1 s XPS spectra of TiO₂ and N—TiOₓ;

FIGS. 15a-e Variable Angle Spectroscopic Ellipsometric (VASE) data for different fabricated films;

FIG. 16a is a graphical representation of the device structure of a MIIM diode consisting of Pt/H—TiO2/TiO2/Al;

FIG. 16b is a graphical representation of the device structure of a MIIM diode consisting of Pt/H—TiO2/N-TiO2/Al, according to a present embodiment;

FIG. 16c is a graphical representation of the device structure of a MIIM diode consisting of Pt/H—TiO2/Al2O3/Al, according to a present embodiment;

FIG. 16d is a graphical representation of the device structure of a MIIM diode consisting of Pt/H—TiO2/N-Al2O3/Al, according to a present embodiment; and,

FIG. 17 is a plot of Resistance vs Responsivity measurements taken by an I-V characterization tool for the dual insulating layer MIIM diodes of FIGS. 16a-16d.

### DETAILED DESCRIPTION

Unless defined otherwise, all technical and scientific terms used herein have the same meaning as commonly understood by one of ordinary skill in the art to which this invention belongs.

As used herein, the term “about” refers to an approximately +/−10% variation from a given value. It is to be understood that such a variation is always included in any given value provided herein, whether or not it is specifically referred to.

The term “plurality” as used herein means more than one, for example, two or more, three or more, four or more, and the like.

The use of the word “a” or “an” when used herein in conjunction with the term “comprising” may mean “one”, but it is also consistent with the meaning of “one or more”, “at least one”, and “one or more than one”.

As used herein, the terms “comprising”, “having”, “including”, and “containing”, and grammatical variations thereof, are inclusive or open-ended and do not exclude additional, unrecited elements and/or method steps. The term “consisting essentially of” when used herein in connection with an apparatus, system, composition, use or method, denotes that additional elements and/or method steps may be present, but that these additions do not materially affect the manner in which the recited apparatus, system composition, method or use functions. The term “consisting of” when used herein in connection with an apparatus, system, composition, use or method, excludes the presence of additional elements and/or method steps. An apparatus, system composition, use or method described herein as comprising certain elements and/or steps may also, in certain embodiments consist essentially of those elements and/or steps, and in other embodiments consist of those elements and/or steps, whether or not these embodiments are specifically referred to.

Generally, the present disclosure provides a Metal-Insulator-Metal (MIM) diode designed for terahertz communication systems. It consists of two metal layers with a defect-engineered insulator between them. The insulator is enhanced through doping, ion implantation, and controlled annealing to improve electron tunneling. The diode operates by leveraging the engineered defects in the insulator to amplify its performance at terahertz frequencies. This allows for efficient rectification and modulation of terahertz waves, enabling high-speed data transfer.

The unique insulator design significantly improves the diode's figures of merit compared to conventional MIM diodes. It achieves higher responsivity while maintaining low resistance, which is crucial for terahertz applications.

In one embodiment, the novel MIM diode is produced with a novel fabrication method. This novel method employs the Atmospheric Pressure Spatial Atomic Layer Deposition (AP-SALD) method. This method enables the fabrication of Al₂O₃ insulating films for MIM nanodiodes. AP-SALD offers several advantages, including speed, scalability, operation at atmospheric pressure in an open-air environment, and precise control of film thickness at the atomic scale. Moreover, it can produce conformal and high-quality films at moderate temperatures, ranging from 80 to 200 °C.

By adjusting the gas phase environment to incorporate precursors, the same AP-SALD system can also facilitate Chemical Vapor Deposition (CVD) under AP-CVD conditions. AP-CVD is particularly advantageous for device fabrication since it achieves higher deposition rates while maintaining smooth, defect-free, and conformal films with thicknesses corresponding to the number of deposition cycles.

The following parts of the description compares the performance of MIM diodes fabricated through AP-CVD with those created using vacuum-based Plasma Enhanced Atomic Layer Deposition (PEALD).

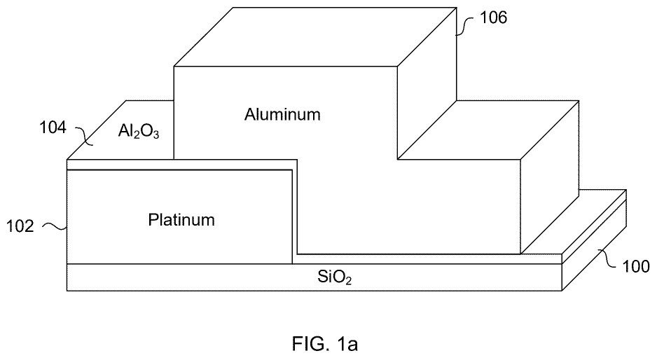

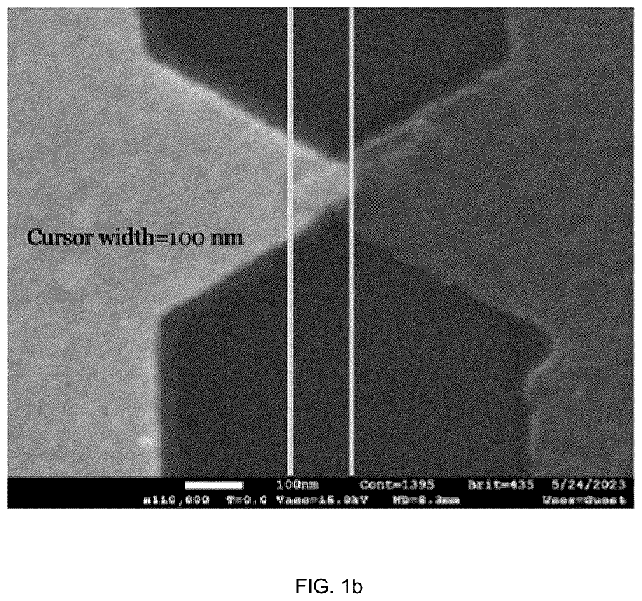

FIG. 1a shows a diagram of cross-sectional view of a Pt—Al₂O₃—Al MIM diode that was fabricated. The wafers used were p-doped silicon wafers with a thermally grown 285 nm silicon dioxide layer 100. Next, the first metal electrodes were patterned using e-beam lithography. Pt 102 was deposited using an e-beam evaporation process. Following this step, an Al₂O₃ layer 104 was deposited on top of the Pt 102. A final Al electrode 106 is formed over the Al₂O₃ layer 104. In the experiments for different embodiments, this layer had different thicknesses ranging from 3 to 9 nm. The Al₂O₃ layer 104 was deposited at 150 °C using AP-CVD and PEALD systems. The details of these deposition conditions are elaborated in the later appearing “Experimental section A” of this description.

It is well known in the art that the consistency of the insulating layer in MIM diodes is a characteristic that contributes to their overall performance and stability. Variations in the insulator's thickness due to the presence of pinholes in the surface region can lead to inconsistencies in the device, causing alterations in the current density and subsequently the tunneling probability. These deviations arise due to the exponential relationship between the current and the electric field in these systems. The presence of unintended defects such as pinholes or traps within the oxide film surface region can lead to conduction mechanisms that are often regarded as detrimental. These issues originate from the metal/oxide interface and can cause substantial external damage to the device, as well as internal damage from defects, reducing its effectiveness and reliability.

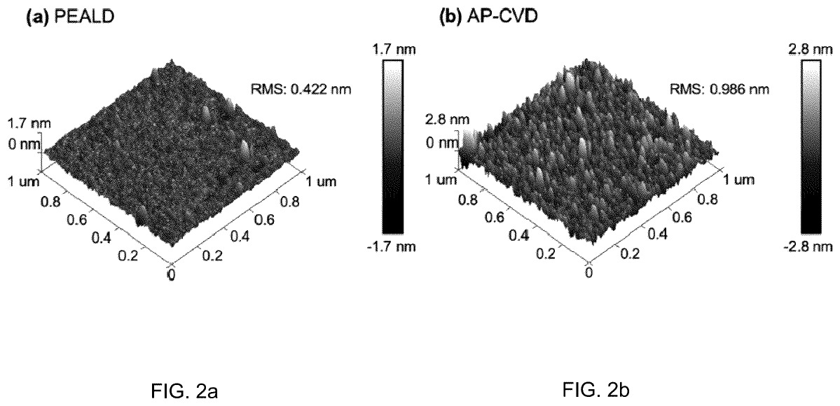

Therefore, achieving a consistently thin and defect-free insulating layer is not just desirable but crucial for the efficient and reliable operation of MIM diodes. The surface roughness of aluminum oxide (Al₂O₃) thin films, which were deposited using PEALD and AP-CVD, was evaluated (see FIG. 2a and FIG. 2b). The roughness of the metal-insulator interface in MIM diodes plays a vital role in determining the tunnelling current and overall performance of the device. A smoother surface of the insulator can improve the breakdown voltage, resulting in a more durable device. On the other hand, increased roughness can lead to higher leakage current, which is undesirable in various MIM diode applications. Additionally, the uniformity of the electric field is critical, non-uniform thickness can cause non-uniform capacitance, which might potentially impact the efficiency of the device in high-frequency applications. Despite the less controlled conditions of an open-air setting, the AP-CVD process produced a thin film with a surface roughness of only 0.986 nm, demonstrating its efficacy in maintaining a low level of roughness. Conversely, the PEALD technique exhibited superior performance, achieving a remarkably low root mean square (RMS) roughness of 0.422 nm, indicating its dominance in achieving highly smooth surfaces.

In the conducted experiments, Aluminum (Al) 106 was used as the secondary metal layer, which was deposited on the insulator 104 through the e-beam evaporation process. It is also patterned by E-beam lithography, and it resulted in a device area of roughly 0.002 μm². The contact area was determined through SEM, as illustrated in FIG. 1b. Platinum 102-Aluminum 106 (Pt—Al) was selected as the electrode pair for two main reasons. Firstly, their significant work function difference is one of the highest reported in current literature at 1.37 eV17. This difference is crucial for obtaining superior performance metrics. Secondly, the combination of Al and the noble metal Pt as electrode materials significantly reduces the chance of forming unwanted oxides at the interfaces, except for aluminum oxide. For devices that utilized PEALD to incorporate Al₂O₃ films 104, a fabrication process similar to the AP-CVD method was employed. Specifically, trimethylaluminum (TMA) was selected as the metal precursor and applied an oxygen (O₂) plasma during the deposition process. 27, 54, and 81 cycles were performed to achieve film thicknesses of 3, 6, and 9 nm, respectively. Ellipsometry was used to verify these measurements. It is worth noting that Atmospheric Pressure Chemical Vapor Deposition (AP-CVD) was more time efficient than PEALD. While the PEALD took 210 s to create a 6 nm film, AP-CVD achieved a similar thickness for the Al₂O₃ layer 104 in just 15 s.

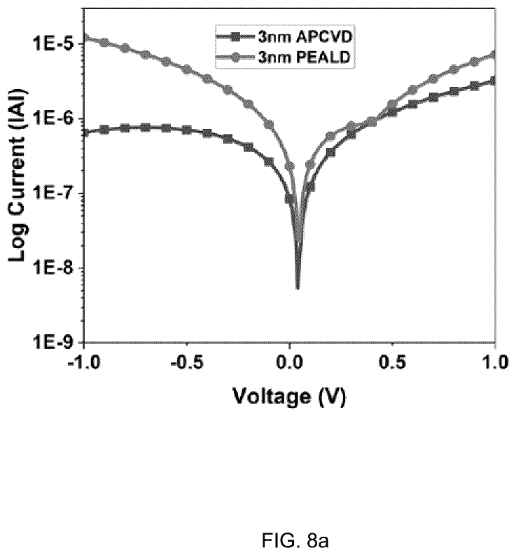

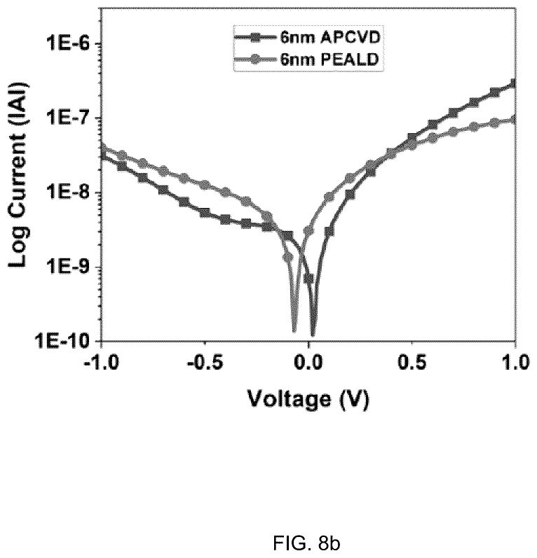

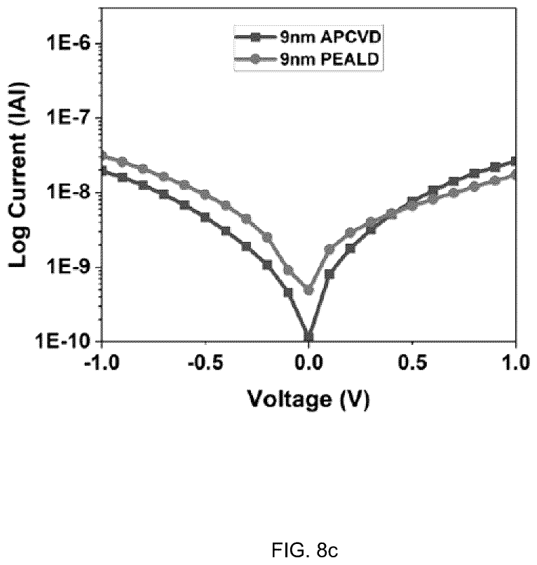

FIGS. 8a-c show measured I-V Curves of the fabricated AP-CVD and PEALD diodes with 3 nm, 6 nm, and 9 nm thicknesses. This shows the relationship between conduction and thickness of the insulating layer.

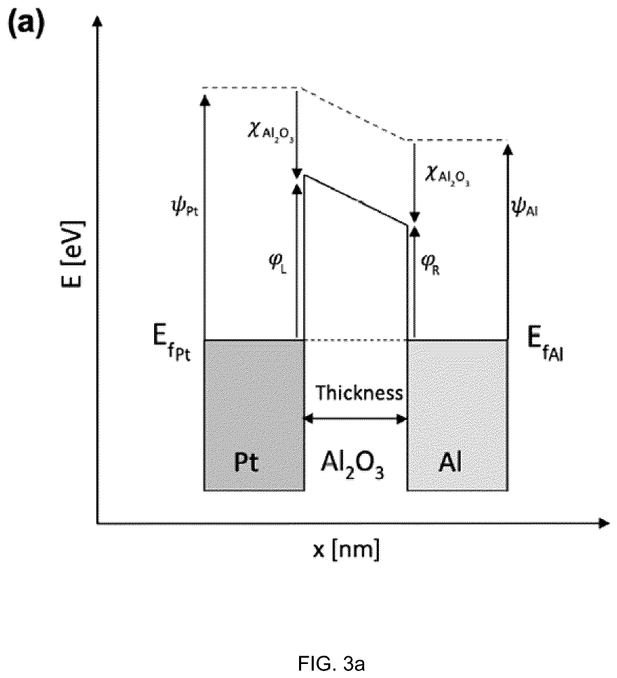

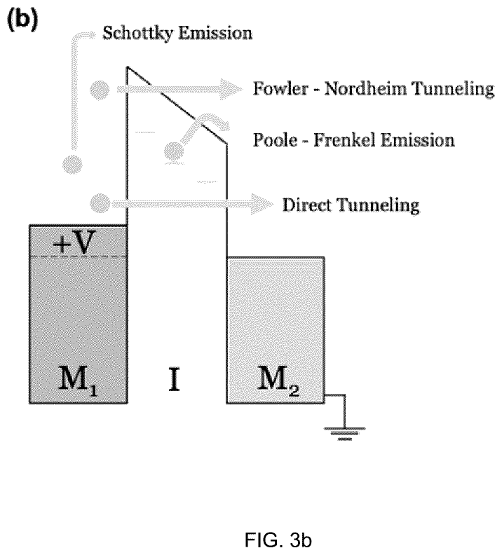

The energy band diagram for the Pt—Al₂O₃—Al MIM diode, including potential barriers at the interfaces, is shown in FIG. 3a. The barrier height (φ) is calculated as the difference between the metal's work function (ψ) and the insulator's electron affinity (χ). The Al₂O₃ produced by PEALD has an electron affinity of 1.90±0.2 eV, while the work functions of Pt and Al are approximately 5.69 eV19 and 4.28 eV20, respectively. As a result, a left barrier height (φ L) of approximately 3.79 eV at the Pt—Al₂O₃ interface, and a right barrier height (φ R) of about 2.38 eV at the Al-Al₂O₃ interface were expected. The thickness of the insulator affects the width of the barrier. MIM diodes based on two different processes were investigated—AP-CVD and PEALD. These were studied over a voltage span in a range from −1 V to +1 V. Conduction mechanisms in an asymmetric positive biased MIM diode are shown in FIG. 3b. In the case of Poole-Frenkel conduction, the movement of electrons through the insulator via trapped states is responsible for conduction. In contrast, Schottky emission is a thermal activation process where conduction occurs as electrons move across the metal-insulator barrier. On the other hand, quantum electron tunnelling can occur across the thin insulator through two distinct mechanisms: direct tunnelling and Fowler-Nordheim tunnelling (FNT). Direct tunneling involves electrons crossing the entire thickness of the barrier, while Fowler-Nordheim tunneling occurs when electrons tunnel across a shorter distance in the triangular region of the barrier, caused by the difference in metal work functions.

Developing MIM diodes that are appropriate for high-frequency applications is a considerable obstacle. The difficulty arises from the need to achieve both low resistance and high responsivity concurrently. The importance of low resistance lies in its contribution to a smaller Resistance-Capacitance (RC) time constant. A decreased RC time constant allows for a higher cut-off frequency, which is a desirable characteristic in high-frequency applications. In order to create an effective rectenna (a rectifying antenna), it is necessary to have a strong connection between the MIM diode and the antenna. For optimal power transfer, the impedance of the antenna needs to match the impedance of the diode. Additionally, efficient rectification requires a high diode responsivity, which quantifies the rectified DC voltage or current produced in response to input power. Responsivity is a metric that gauges the MIM diode's capacity to generate direct current (DC) when exposed to alternating current (AC) electrical power. This parameter is determined by dividing the second derivative of the I-V curve by twice the first derivative at a given bias voltage.

$$Responsivity = \frac{1}{2} ( \frac{{d}^{2} I}{d {V}^{2}} / \frac{dI}{d V} ) \qquad ( 1 )$$

The responsivity equation is shown in Eq. (1) above. I is the current in amperes (A), V is the voltage in volts (V). Responsivity is influenced by multiple factors including the choice of metal and insulator, the thickness of the insulator, and the barrier heights between the metals and the insulator.

Table 1 presents a comparison of diode performance using different fabrication methods for Al₂O₃ films in various studies: AP-CVD and PEALD. The parameters examined include maximum responsivity, near zero-bias responsivity, and near zero-bias resistance. In the current study, the diode produced using the AP-CVD process with a 6 nm Al₂O₃ layer showed significantly reduced resistance, measuring at 25×10⁶Ω. This resistance level is notably lower than what was observed in previous research findings. This improvement can be attributed to the replacement of reactive ion etching (RIE) with wet etching for removing the oxide layer on top of the electrode. The motivation behind shifting from RIE to wet etching was to decrease contact resistance. In RIE, the surface is bombarded by ions in a non-selective manner, which could increase the roughness of the metal layers and consequently raise the contact resistance in previous studies. On the other hand, wet etching is a gentler and more uniform process that preserves the integrity of the underlying material. As a result, it produces a smoother surface, and prior research by others has shown a correlation between smoother surfaces and lower contact resistance. Furthermore, wet etching facilitates a cleaner interface between the aluminum and the contact electrode, reducing the potential risks associated with a rough surface. To enhance these advantages, a gold layer was deposited immediately after the oxide wet etch to prevent further oxidation of the aluminum layer. Overall, both the experimental results and existing findings indicate that transitioning from RIE to wet etching can lead to the creation of smoother and more stable interfaces, resulting in reduced contact resistance.

TABLE 1

| | Near zero | Near zero | Maximum |
|---|---|---|---|
| | bias | bias | responsivity |
| | resistance | responsivity | (0-1 V) |
| | (Ω) | (AW⁻¹) | (AW⁻¹) |
| 6 nm PEALD Diodes | 40 × 10⁶ | 0.4 | 6.1 |
| (Current Study) | | | |
| 6 nm AP-CVD Diodes | 25 × 10⁶ | 0.2 | 5.02 |
| (Current Study) | | | |
| 6 nm PEALD Diodes | 7 × 10¹² | −1 | 3.5 |
| (Prior Study [symbol] ) | | | |
| 6 nm AP-CVD Diodes | 5 × 10¹³ | 6.5 | 6.5 |
| (Prior Study [symbol] ) | | | |

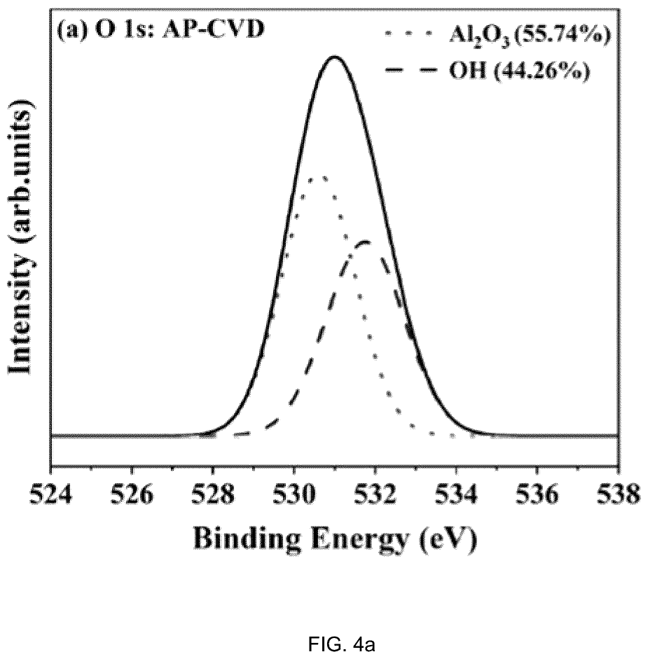

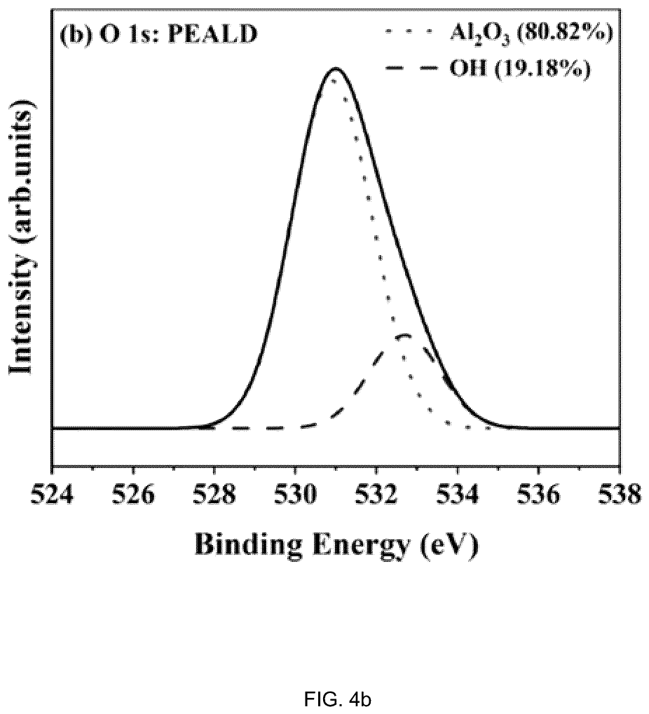

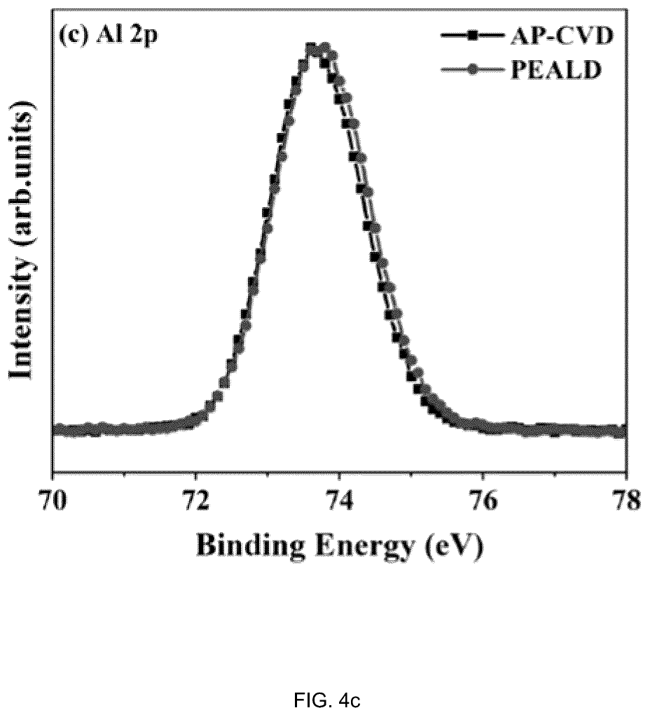

The AP-CVD diodes fabricated with a 6 nm Al₂O₃ layer demonstrate lower resistance compared to PEALD diodes, with the resistance measured at approximately 40×10⁶Ω. This observed difference can be attributed to the presence of defects in the AP-CVD diodes. The X-ray photoelectron spectroscopy (XPS) results depicted in FIG. 4a to FIG. 4c reveal, AP-CVD diodes exhibit a higher concentration of OH— ions. FIG. 4a shows the effect of having defects, while FIG. 4c shows the effect of Al concentration on the devices.

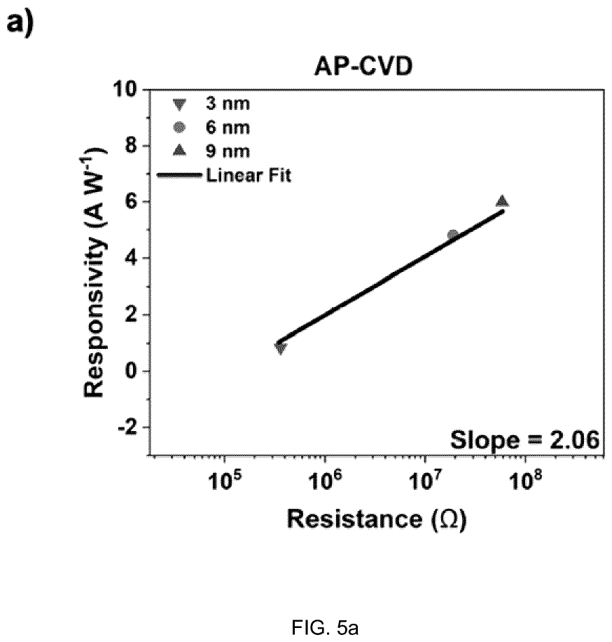

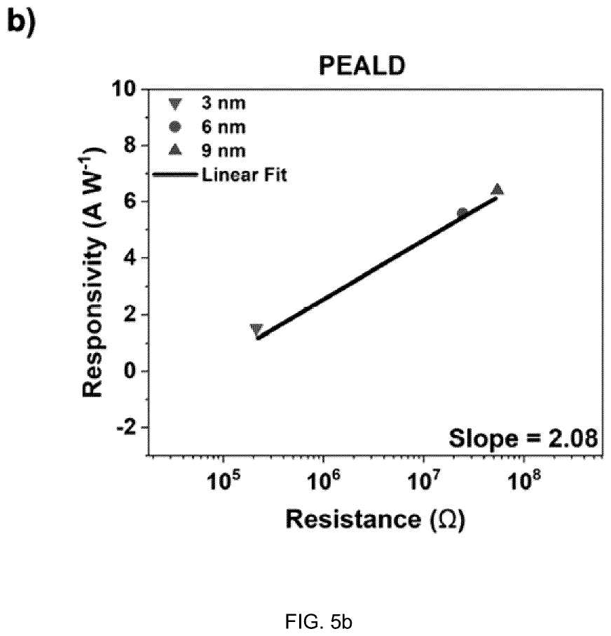

The presence of these ions facilitates enhanced Poole-Frenkel (PF) conduction, which in turn leads to a decrease in resistance. This observation aligns with findings from previously reported studies. Moreover, this work on PEALD shows a doubled maximum responsivity value, which can be attributed to improved contact between the probe station and electrodes, while the maximum responsivity value for AP-CVD remains unchanged. FIGS. 5a and 5b illustrates the relationship between Responsivity and Resistance for the diodes that were produced. The graph's slope denotes the Responsivity/Resistance ratio. By employing a thicker insulator, the occurrence of electron tunnelling is minimized, resulting in a lower on-state current. However, this also enhances the responsivity of the diode. The slope of the graph represents the Responsivity/Resistance ratio, where a higher value indicates improved rectification performance at high frequencies. Achieving high rectification efficiency requires a high responsivity, as well as low resistance for optimal antenna coupling and a low RC constant. FIGS. 5a and 5B indicates a similar slope for AP-CVD (2.06) and PEALD (2.08). Based on the slopes, it can be inferred that diodes created using AP-CVD could potentially demonstrate compatible performance at high frequencies when compared to diodes produced using PEALD.

Nevertheless, when considering variables such as production cost and processing speed, AP-CVD emerges as a more advantageous option compared to PEALD. Also, the AP-CVD diode's performance has been observed to be competitive with previously reported THz diodes that utilized a single layer of Al₂O₃ and PEALD fabricated diodes. This comparison is based on the parameters of responsivity and resistance. The exceptional performance characteristics exhibited by AP-CVD diodes can be attributed to various factors, such as the conduction mechanisms involved, the barrier heights between the metals and insulator, surface roughness, and the presence of defects in the insulator. It is noted that the original hypothesis—that being defect free—is not as advantageous as originally believed. The anticipated conduction processes in MIM diodes encompass three significant mechanisms: Poole-Frenkel (PF), Schottky emission (SE), and quantum electron tunnelling.

Following is an outline of the fabrication steps for the formation of the Al₂O₃ insulating layer of the disclosed Pt—Al₂O₃—Al diode using AP-CVD and PEALD.

Parameters for AP-CVD Al₂O₃:
Precursors:
Trimethylaluminum (TMA)
H₂O
TMA Vapor Generation:
Bubbling TMA liquid with N₂ gas at 20 sccm
TMA vapors mixed with 130 sccm N₂ carrier gas
H₂O Vapor Generation:
Bubbling water with N₂ gas at 45 sccm
H₂O vapors mixed with 255 sccm N₂ carrier gas
Additional N₂ Gas Line:
1200 sccm N₂ to partially separate precursors at the reactor surface and remove excess by-products
Substrate Parameters:
Temperature: 150 °C
Oscillation Speed: 30 mm s⁻¹
Film Growth:
Film Thickness: 6 nm achieved with 9 oscillations (36 sequential exposures)
Growth Rate: 0.17 nm/cycle (higher than 0.11 nm/cycle for PEALD)
Verification:
Thickness confirmed by ellipsometry measurements
   Parameters for PEALD Al₂O₃:
Precursors:
Trimethylaluminum (TMA)
O₂ plasma
Deposition Cycles:
27 cycles for 3 nm thickness
54 cycles for 6 nm thickness
81 cycles for 9 nm thickness
Equipment:
Oxford-Cluster system
Chamber Conditions:
Substrate Temperature: 150 °C
Base Pressure: below 10⁻⁶ torr
Load Lock Pressure: below 10⁻⁵ torr
Process Steps:
Chamber Purge:
Purged with Ar for 3 minutes to stabilize pressure and temperature
TMA Dosage:
TMA bubbled with Ar
Dosage Time: 20 ms at 15 mtorr
Precursor line purged with Ar for 1 s at 15 mtorr
O₂ Plasma Generation:
O₂ flow stabilized for 500 ms
Plasma generated using RF power of 300 W at 15 mtorr
Substrate exposed to O₂ plasma for 2 s
Final Purge:
Purged with Ar for 1 s at 15 mtorr
Film Growth:
Growth Rate: 0.11 nm/cycle

The PEALD growth rate is lower than the 0.17 nm/cycle achieved with AP-CVD.

In summary, AP-CVD results in defects in the insulator due to exposure to atmospheric gases, while PEALD generally produces defect-free films because it operates in a low-pressure vacuum environment.

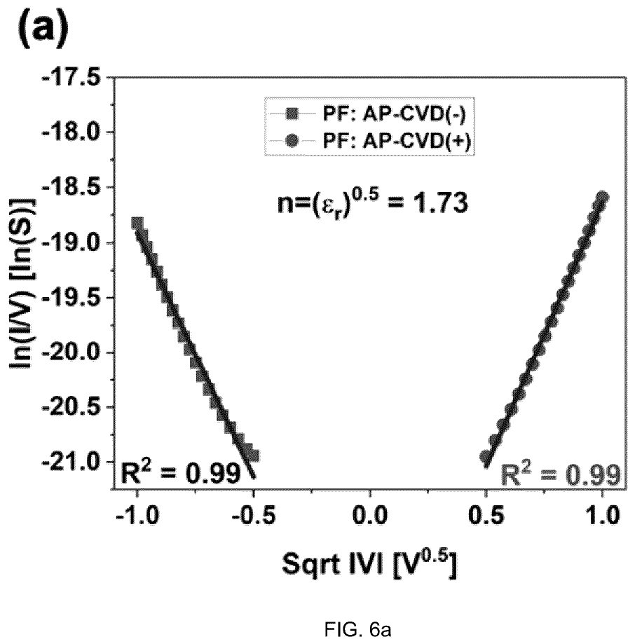

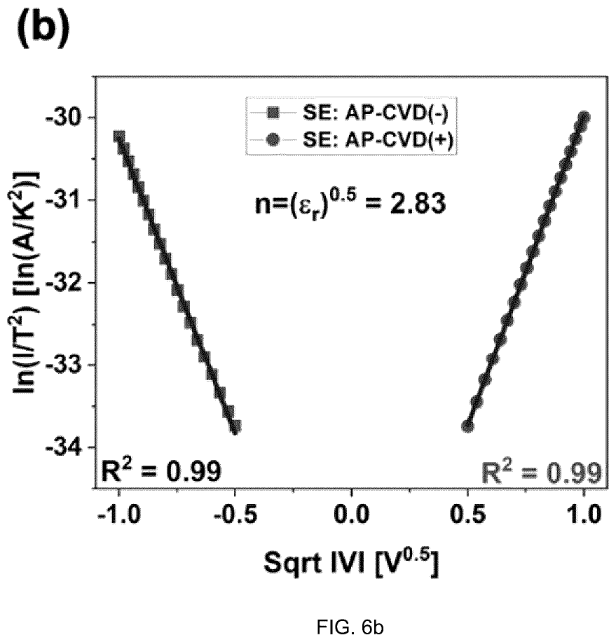

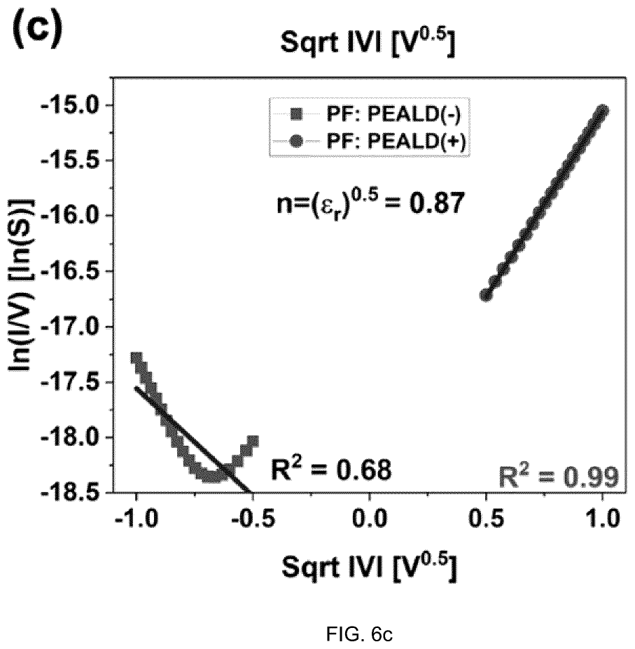

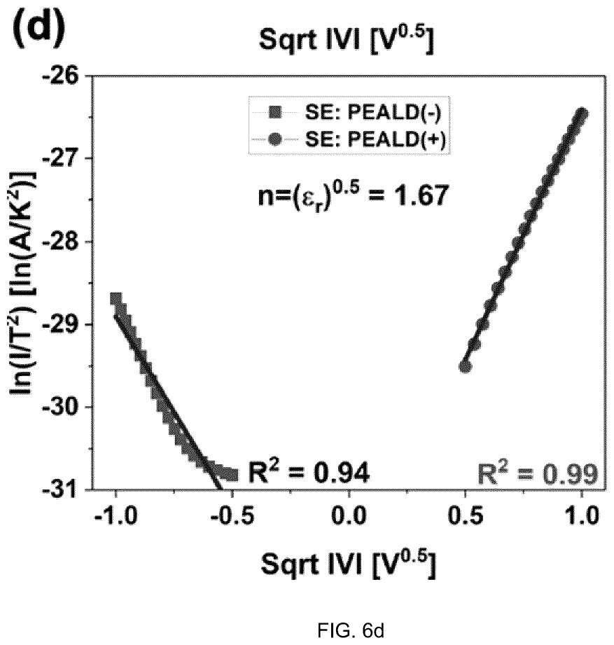

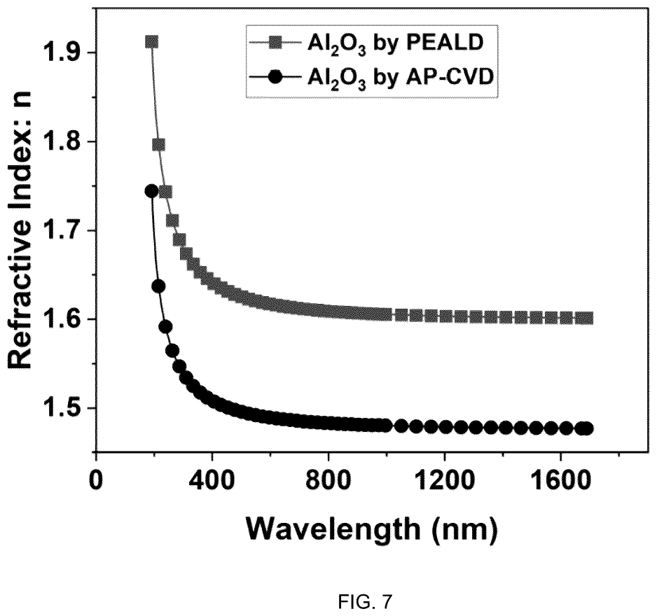

The relative permittivity (Er) of the AP-CVD and PEALD diodes was determined using equations derived from Poole-Frenkel, Schottky Emission, and Fowler-Nordheim that are shown in the supporting document. It was observed that at lower voltage biases, Poole-Frenkel conduction was the primary mechanism in AP-CVD diodes, while Schottky emission was the dominant mechanism in PEALD diodes under similar conditions. At higher voltage biases, regardless of the Al₂O₃ deposition method used, Fowler-Nordheim tunnelling emerged as a significant conduction mechanism. FIGS. 6a to 6d displays the I-V data for the AP-CVD diode, with (a) Poole-Frenkel and (b) Schottky emission fits at low voltage biases (0.09-1 V). The conduction mode is indicated by squares for negative polarity and circles for positive, pointing to a dominant mechanism. Correlations with an R2 value above 0.99 confirm this dominance and corresponding refractive indices are provided. The Poole-Frenkel fits in FIG. 6a (R²=0.99 and R²=0.99) and Schottky emission fits in FIG. 6b (R²=0.99 and R²=0.99) show similar results. However, the extracted dielectric constants differ between these fits. The Er obtained from the Poole-Frenkel fits in FIG. 6a is 3.06, while the Schottky emission fits in FIG. 6b indicate εᵣ=8. The dynamic dielectric constant, εᵣ=n², which was measured by ellipsometry, ranges from 1.47 to 1.74 for AP-CVD Al₂O₃ and 1.60-1.91 for PEALD Al₂O₃ (FIG. 7). The value εᵣ=3.06 from the Poole-Frenkel fitting corresponds to a refractive index n=(εᵣ)0.5=1.73, which aligns well with the measured range of 1.47-1.74 by ellipsometry.

These findings suggest that Poole-Frenkel conduction is the dominant mechanism in AP-CVD diodes at low voltage biases. FIGS. 6c and 6d illustrate the I-V data for the PEALD diode, fitted with (c) Poole-Frenkel and (d) Schottky emission relations at low voltage biases. For PEALD diodes, the Schottky emission plots in FIG. 6d yield better fits (R²=0.94 and R²=0.99) compared to the Poole-Frenkel plots in FIG. 6c (R²=0.68 and R²=0.99). Furthermore, the refractive index n=1.67 obtained from the Schottky emission plots matches the range of 1.60-1.91 measured by ellipsometry. This indicates that Schottky emission is the dominant conduction mechanism in PEALD diodes at low voltages.

The cut-off frequencies were determined by employing Eq. (2) below and obtained Er values via ellipsometry measurements. The resistance R, denoted in ohms, for the 3, 6 and 9 nm thick insulator diodes can be found in FIG. 5. The capacitance C is in farads, so is the permittivity of free space, Er is the relative permittivity, A represents the area in square meters, and d denotes the insulator thickness in meters. Despite the presence of resistances on the order of MO, the diminutive surface area of the diodes—with the smallest reaching 0.002 μm²—suggests that the fabricated diodes have the potential to operate within the Terahertz Gap, which spans from 0.1 to 10 THz. Cleanrooms have traditionally been considered essential for producing high-quality insulator films. However, findings from the experiments challenge this perspective, suggesting that cleanroom conditions are not invariably necessary. Specifically, diodes with a size of 3 nm fabricated through PEALD and AP-CVD processes demonstrate potential cut-off frequencies of 0.36 THz and 0.19 THz, respectively. This data supports the notion that quantum mechanical devices can be successfully produced outside stringent cleanroom facilities. Notably, while reducing the diode area may further improve the cut-off frequency, there are limitations. Scaling below 0.002 μm² is hindered by the vertical thickness of the MIM nanodiodes. A promising strategy for boosting device performance could encompass the utilization of materials with a reduced refractive index or minimizing the resistance.

$${f}_{cut} = \frac{1}{2 π RC} = \frac{d}{2 π R {ε}_{0} {ε}_{r} A} \qquad ( 2 )$$

The unique electrical properties of AP-CVD and PEALD diodes under low voltage conditions can be understood by applying XPS on Al₂O₃ films produced by these two methods. This analysis technique sheds light on the chemical composition and bonding structure of the material. By examining the O 1 s peaks through a Gaussian fit, as shown in FIGS. 4a and b, distinct peaks at 531 eV and 532.3 eV respectively were detected. These values represent O⁻² in Al₂O₃ and hydroxyl OH— groups, respectively. To determine the fraction of the O 1 s signal assigned to these components in the Al₂O₃ films produced by AP-CVD and PEALD, the areas under the associated XPS peaks were computed. As expected, the AP-CVD Al₂O₃ film, depicted in FIG. 4a, presented a greater concentration of OH— groups. This is attributable to the employment of H₂O as the oxygen precursor in the AP-CVD process, as confirmed by reference. It is crucial to realize that the XPS data only cover the surface of the material, and the low-temperature thermal deposition process involving H₂O tends to leave a substantial amount of OH— on the film surface. This increased presence of OH— could be a result of incomplete precursor reactions and the significant energy required for water to evaporate at lower temperatures. These hydroxyl groups are expected to function as electron traps in the films, encouraging Poole-Frenkel conduction at low voltages, which is in line with the dominant Poole-Frenkel conduction observed in the AP-CVD diodes in FIG. 6a. Contrastingly, the O 1 s peak corresponding to the Al₂O₃ component in the PEALD film, portrayed in FIG. 4b, is considerably higher. This can be credited to the high reactivity related to the PEALD process, which uses O⁻² plasma and results in denser films, can be seen in AFM figures in FIG. 2. This conclusion is in agreement with the higher percentage of Al noticed in the PEALD film, as stated in Table S2 below, and the elevated refractive index recorded in FIG. 7. Furthermore, the Al 2p spectra of both the AP-CVD and PEALD Al₂O₃ films in FIG. 4c feature a peak at 74 eV, a value associated with Al₂O₃.

TABLE 2

| | Film Compositions (at %) | | | |
|---|---|---|---|---|
| Technique | O | Al | C | O/Al |
| PEALD | 53.6 | 39.1 | 7.3 | 1.37 |
| AP-CVD | 55.2 | 36.7 | 8.1 | 1.5 |

In Table 2, the film compositions of Al₂O₃ films deposited using the PEALD and APCVD techniques were analyzed through X-ray Photoelectron Spectroscopy (XPS).

Carbon was detected in both the AP-CVD and PEALD Al₂O₃ films. The presence of carbon contamination is typically attributed to the use of organometallic precursors and airborne contamination.

### Experimental Section A

According to a present embodiment, a fabrication process for an MIM diode is now described.

A 100 nm thick bottom Platinum (Pt) electrode was deposited on p-type Si substrates with a 285 nm thermal SiO₂ layer using an Angstrom E-beam evaporation system. The base pressure was set to 4×10⁻⁶ torr and the deposition rate was 3 A°s⁻¹. The Pt electrodes were patterned using E-Beam lithography with a RAITH EBL.

The Al₂O₃ thin films were acquired via AP-CVD using trimethylaluminum (TMA) and H₂O precursors. In the AP-CVD process, the TMA liquid precursor was bubbled with N₂ gas at a flow rate of 20 sccm to generate the vapors of TMA. The TMA vapors were then mixed with 130 sccm of N₂ gas, which works as a carrier gas to assist in TMA delivery to the reactor head. Similarly, H₂O vapors were generated by bubbling the water with 45 sccm of N₂ gas and were mixed with N₂ carrier gas of 255 sccm. A separate N₂ gas line with a flow rate of 1200 sccm was used to partially separate the precursors at the reactor surface and also to remove excess unreacted precursors or reaction by-products. The thickness of the film was controlled by adjusting the speed and number of oscillations. The substrate temperature and oscillation speed were set at 150 °C and 30 mm s⁻¹, respectively. A 6 nm thin film was grown with nine oscillations, as verified by ellipsometry measurements. The nine oscillations of the substrate corresponded to 36 sequential exposures of both TMA and H₂O precursors, resulting in a growth rate of 0.17 nm/cycle, which was higher than the 0.11 nm cycle⁻¹ rate achieved for PEALD of Al₂O₃ in the present experiments.

Devices with PEALD films were fabricated using similar steps. TMA and O₂ plasma precursors were used, and 27, 54 and 81 cycles were used to deposit a 3, 6, and 9 nm thick film. The film was deposited at the same temperature of 150 °C using an Oxford-Cluster system with a base pressure below 10⁻⁶ torr and the load lock pumped below 10⁻⁵ torr. The vacuum chamber was first purged with Ar for 3 min to stabilize the chamber pressure and temperature. TMA bubbled with argon was used to dose the substrate for 20 ms at a pressure of 15 mtorr, followed by purging the precursor line with Ar for 1 s at a pressure of 15 mtorr. Afterward, an O₂ flow was stabilized for 500 ms before generating plasma using radio frequency (RF) with a power of 300 W at a pressure of 15 mtorr. The substrate was exposed to the O₂ plasma for 2 s and then purged with Ar for 1 s at a pressure of 15 mtorr.

A 100 nm thick top Aluminum (Al) electrode was deposited on insulator thin films. Angstrom E-beam evaporation system used for the deposition. The base pressure was set to 4×10⁻⁶ torr and the deposition rate was 3 A°s⁻¹. The Al electrodes were patterned using E-Beam lithography with a RAITH EBL. Wet etching was used to remove any oxidant on top of the electrode layers.

The I-V properties of the MIM diodes were measured using a Keithley 4200-SCS semiconductor characterization system connected to a Everbeing Probe Station C-8. The thickness and refractive indices of the 3, 6, 9 nm thick films were measured using a Woollam M-2000 DI ellipsometer with a wavelength range of 200-1800 nm, utilizing the CodyLor formula model. Bruker Icon Atomic Force Microscope was utilized to characterize film uniformity and surface roughness. The chemical states of the films were determined through X-ray photoelectron spectroscopy (XPS) using a Thermo ESCALAB 25 instrument with an Al-Ka X-ray source. XPS analyses were conducted by applying the Shirley baseline and employing Gaussian fitting.

The presently described embodiments demonstrates the successful development of new Pt—Al₂O₃—Al nanodiodes. This small design offers potential for operations within the THz gap. These nanodiodes utilize a thin Al₂O₃ insulating film, which is deposited in an open-air environment using a rapid and scalable method. To achieve this, Atomic Layer Deposition System (AP-SALD) was used under Chemical Vapor Deposition (CVD) conditions. This approach allowed for the fabrication of MIM diodes with high-quality insulator films without any pinholes in a shorter time compared to the conventional PEALD method.

From the above experiments, the investigation of MIM diodes produced using AP-CVD, it was discovered that Poole-Frenkel emission was the dominant conduction mechanism at lower bias voltages. This phenomenon is consistent with the higher roughness observed on the surfaces of AP-CVD films compared to those deposited using PEALD. Moreover, it is also attributed to a higher concentration of hydroxyl groups in the films, indicating that the non-uniformity in the insulator layer results in the formation of trapped states. In contrast, MIM diodes utilizing aluminum oxide (Al₂O₃) deposited via PEALD exhibited remarkable uniformity and predominantly displayed Schottky emission at low bias voltages. These findings highlight the significant influence of the fabrication technique on the uniformity of the insulator layer, subsequently affecting the conduction mechanisms and overall performance of the devices. Importantly, the differences in insulator uniformity resulting from the distinct deposition methods led to variations in electrical behaviors and different figures of merit.

Furthermore, calculations were conducted to determine the theoretical cut-off frequencies for the fabricated diodes. The results indicate that diodes created using both AP-CVD and PEALD methods can operate in the THz range. Additionally, there are opportunities for further improvements, such as reducing resistance and exploring alternative materials with different refractive indices.

While the primary focus of the experiments was on a simple MIM structure, future research can expand this approach to include multi-insulator diodes. These diodes could address the challenge of high diode resistance while enhancing performance by reducing the effective tunnelling distance. Another potential approach to enhance diode performance is enabling resonant tunnelling of electrons. Recent studies have also demonstrated that a defect-engineering approach can enhance the figures of merit without causing an undesirable increase in diode resistance. This scalable technique has broader applications, including resistive switching memories and metal-insulator-semiconductor diodes. Despite the continued reliance on vacuum and lithography techniques for metal electrode deposition and device patterning, the previously described method embodiment of depositing the insulator layer represents a significant step toward the cost-effective and scalable manufacturing of THz devices.

According to another embodiment, a defect-engineered insulator for Metal-Insulator-Metal (MIM) diode is disclosed, which offers a novel solution to the challenges of terahertz communication. Following is a description of a carefully controlled in-situ doping in low temperature that create an insulator with a tailored electronic structure. This structure enhances electron tunneling at terahertz frequencies while maintaining low resistance. The engineered defects act as stepping stones for electrons, facilitating their movement across the insulator barrier. This results in higher responsivity compared to conventional MIM diodes, without sacrificing the low resistance crucial for high-frequency operation.

The improved design significantly enhances the conversion of terahertz waves into electrical signals. This addresses a key limitation of other technologies like Schottky diodes, which suffer from performance degradation at terahertz frequencies. The diode of the present embodiment maintains its efficiency across the terahertz range, enabling better signal processing and detection.

While signal attenuation remains a challenge in terahertz communication, the presently described technology mitigates this issue through improved conversion efficiency and low resistance. This allows for stronger signal generation and detection, maintaining better signal integrity compared to other approaches. Unlike Quantum Cascade Lasers that require cryogenic cooling, the presently described defect engineered MIM diodes operate at room temperature, making them far more practical for real-world communication systems.

The controlled nature of the electron tunneling process in the present insulator design helps to minimize random fluctuations that contribute to noise. This results in cleaner signals and improved communication quality compared to alternatives like Impatt diodes. This technology also offers better scalability and tunability than emerging technologies like graphene-based devices. The defect engineering process can be fine-tuned to optimize performance for specific frequency ranges within the terahertz spectrum.

The presently described defect-engineered insulator for MIM diodes provides a comprehensive solution to the challenges of terahertz communication. It addresses core issues of responsivity, resistance, and signal conversion efficiency while offering practical advantages in implementation and scalability.

Titanium dioxide, TiO₂, finds widespread use in diverse fields such as sensor technology, photovoltaic systems, and photocatalysis for environmental and energy applications, including self-cleaning surfaces, water, and air purification. Its popularity stems from its chemical stability, cost-effectiveness, abundance, and non-toxic nature. However, TiO₂, particularly in its anatase form, encounters limitations due to its large bandgap of 3.3 eV. Additionally, the conduction band's position (CB) in TiO₂ impacts the electron transport in various devices, including photovoltaics and metal-insulator-metal (MIM) diodes, affecting their overall performance.

To enhance the current-voltage characteristics of TiO₂, various doping methods have been employed. Metal and non-metal doping involves the strategic incorporation of metals such as gold (Au), silver (Ag), iron (Fe), and non-metals such as boron (B), carbon (C), and nitrogen (N) into the TiO₂ lattice. Since these dopants replace oxygen or create oxygen vacancies, the stoichiometry of titanium dioxide changes from TiO₂ to TiOₓ. TiOₓ is non-stoichiometric titanium dioxide—meaning the oxygen-to-titanium ratio isn't exactly 2:1 like in stoichiometric TiO_{Z}. The “x” indicates that the oxygen content is variable, typically with x<2, meaning the material is oxygen-deficient. This process is typically achieved during synthesis using techniques like physical vapor deposition, sol-gel processes, or chemical vapor deposition. These dopants are introduced to create new energy levels within the TiO₂ bandgap, termed mid-gap states. While doping narrows the bandgap of TiO₂, it often introduces trap states that act as recombination centers for carriers. To address this, prior researchers introduced a passivated co-doping approach, which involves the passivation of these trap states to prevent them from acting as carrier recombination centers. They explored Mo—C co-doping, using transition metals such as V, Cr, Nb, and Mo as n-type dopants for Ti sites, and N and C as p-type dopants for 0 sites. This strategy uses charge-compensated donor-acceptor pairs (e.g., N—V, Nb—N, Cr—C, Mo—C) to stabilize the electronic structure and narrow the bandgap effectively.

Black titanium dioxide has emerged as a novel class of material that exhibits significant enhancements in optical properties, particularly in visible light absorption, due to its reduced bandgap. In black TiO₂, the presence of Ti³⁺ ions and oxygen vacancies introduces multiple defect levels within the bandgap, which extends the optical absorption spectrum into the visible region. Additionally, the process of hydrogenation contributes to this effect by generating free hydrogen, which also aids in extending absorption to longer wavelengths. The visible light absorption is primarily attributed to mid-gap levels overlapping with the O2p and Ti3d orbitals, and the disorder in the amorphous hydroxylated structure of TiO₂ further alters the electronic structure, inducing band tails that narrow the bandgap. Various methods have been utilized to synthesize black TiO₂, including plasma treatment, NaBH4 reduction, and reductions with metals like aluminum and magnesium. The high-pressure hydrogenation of TiO₂ is a notable synthesis technique because it effectively modifies the material's structure. By heating the TiO₂ and then rapidly cooling it, this method prevents the reformation of its stoichiometric structure, leading to desired material properties. However, it is generally expensive due to the need for high temperatures and pressures.

The presently described embodiment is a simple and rapid method for plasma assisted atomic layer deposition (PAALD) to achieve black TiO₂ by in-situ hydrogenated TiOₓ for the first time. Doping TiO₂ with hydrogen typically requires significant energy due to the unfavorable thermodynamics of breaking Ti—O bonds during hydrogenation. To address this challenge, pure hydrogen plasma was utilized and avoided the use of O₂ precursor sources, thereby inhibiting the formation of Ti—O bonds and enhancing the likelihood of hydrogen reacting with titanium. Residual water vapor in the PAALD chamber served as an unintended oxygen source at a relatively low pressure of 5×10⁻⁴ Pa. Given this context, titanium isopropoxide (TTIP) was selected as the titanium precursor due to its high reactivity with water vapor. Despite the minimal presence of water vapor compared to hydrogen, its stronger affinity for the titanium precursor significantly aids the formation of hydrogen-doped TiOₓ (H—TiOₓ). By minimizing the oxygen content and employing a pure H₂ plasma, the incorporation of hydrogen into the TiO₂ films is enhanced, resulting in effectively hydrogenated TiOₓ. The performance of H—TiOₓ MIM diodes was demonstrated and shown the enhanced current-voltage characteristics compared to undoped TiO₂ and nitrogen-doped TiOₓ (N—TiOₓ) based diodes. The experimental results from the present embodiment establishes that H—TiOₓ is a very suitable candidate for high-frequency applications due to its unique electrical characteristics. Achieving higher responsivity while simultaneously reducing diode resistance remains a significant challenge in diodes. The present embodiment presents an alternative and novel approach, demonstrating for the first time that it is possible to achieve both lower resistance and higher responsivity using dopants in metal-single insulator-metal diodes.

An experiment was conducted to validate the effectiveness of the presently described embodiment.

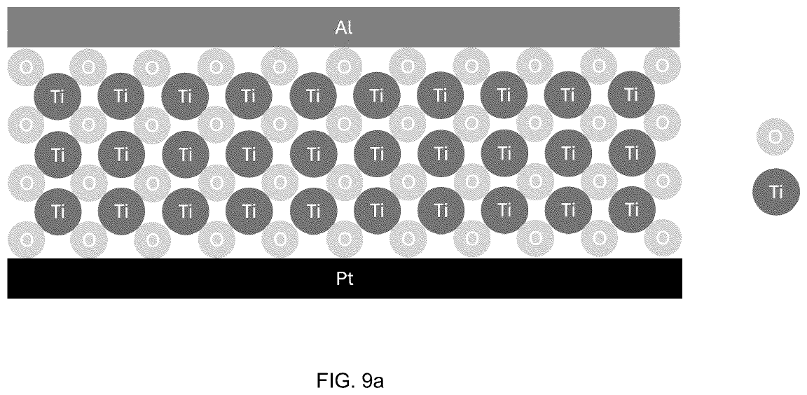

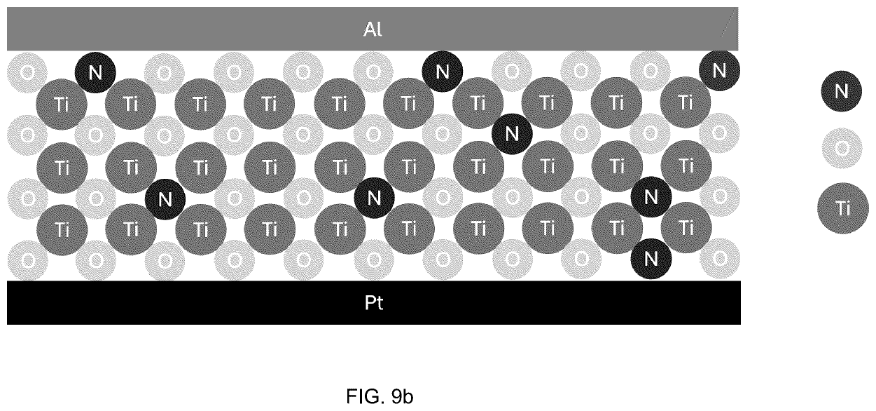

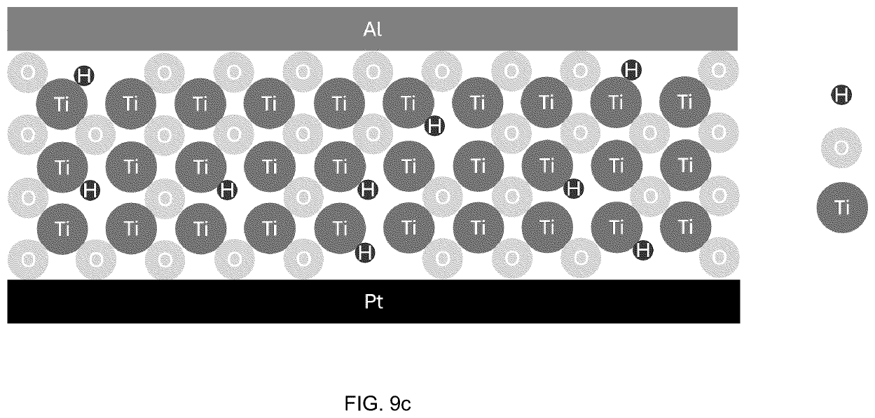

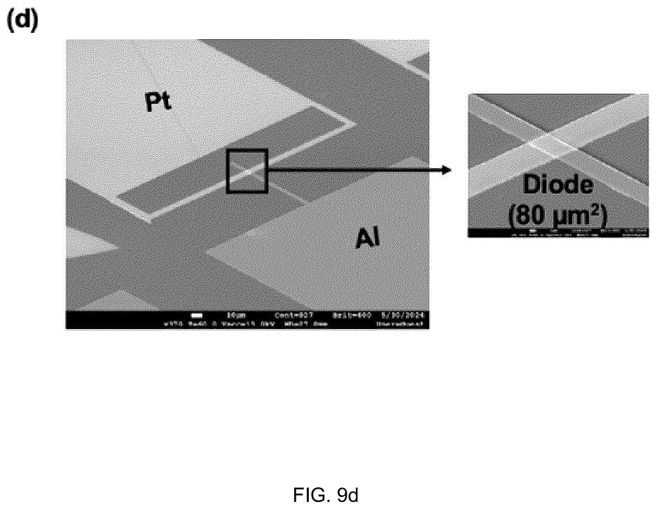

Five types of diodes were fabricated in this work. An undoped Pt/TiO₂/Al and a nitrogen-doped Pt/N-TiOₓ/Al diodes were fabricated as reference devices, which are known in the prior art, shown in FIGS. 9a and 9b. Three types of hydrogen-doped Pt/H—TiOₓ/Al diodes were fabricated with different hydrogenation times: 1 s, 3 s, and 6 s as demonstrated in FIG. 9c. Each type, fabricated on 2 cm by 2 cm silicon wafers, had areas of 4 μm², 40 μm², and 80 μm², as defined by lithographic patterning of the Pt and Al contacts, shown in FIG. 9d. All insulator films were deposited using PAALD. For the deposition of TiO₂, the standard fabrication process suggested by the equipment supplier was used. In this experiment, Oxford Instruments was the supplier, however any known TiOₓ recipe can be used. The gases used, plasma exposure times, and number of cycles for TiO₂ and N—TiOₓ are detailed in Table 3 and the later described Experimental Section B. For the H—TiOₓ, a novel hydrogen plasma technique developed in this study was employed, using hydrogen plasma as the hydrogen source in a remote PAALD system. Historically, H—TiOₓ has been produced via hot-filament chemical vapor deposition assisted by a hydrogenation process, and by sputtering. In the present experiments, doping TiO₂ with hydrogen was found challenging due to the thermodynamic difficulty in breaking Ti—O bonds using hydrogen atoms. To facilitate the formation of H—TiOₓ, no O₂ precursor sources were used; instead, a pure hydrogen plasma was applied to inhibit the formation of Ti—O bonds, allowing hydrogen atoms to react with the titanium.

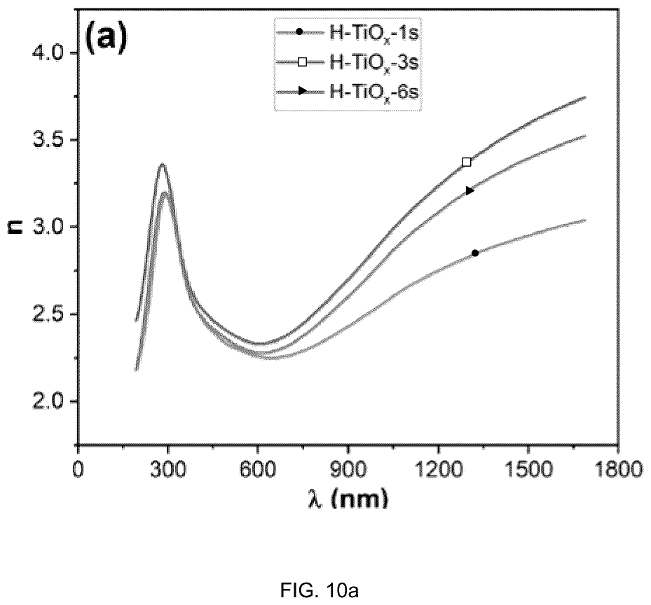

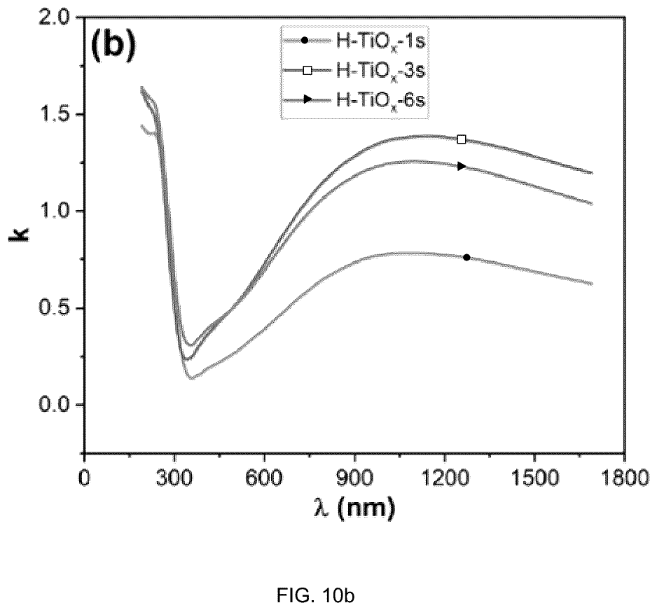

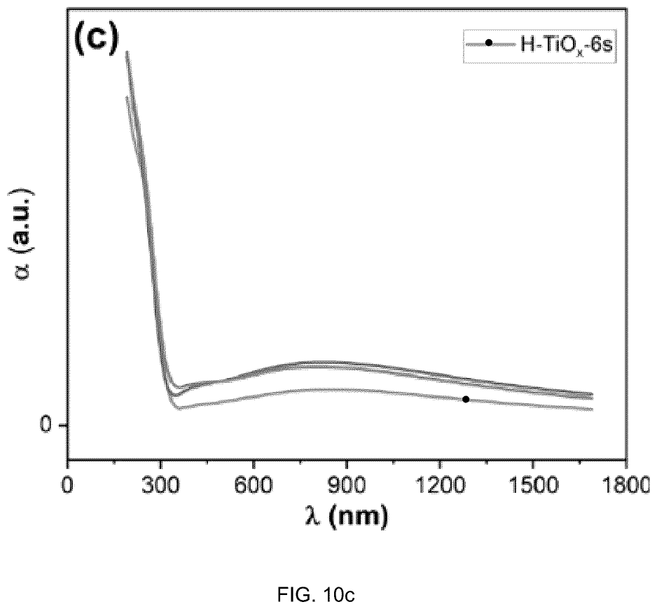

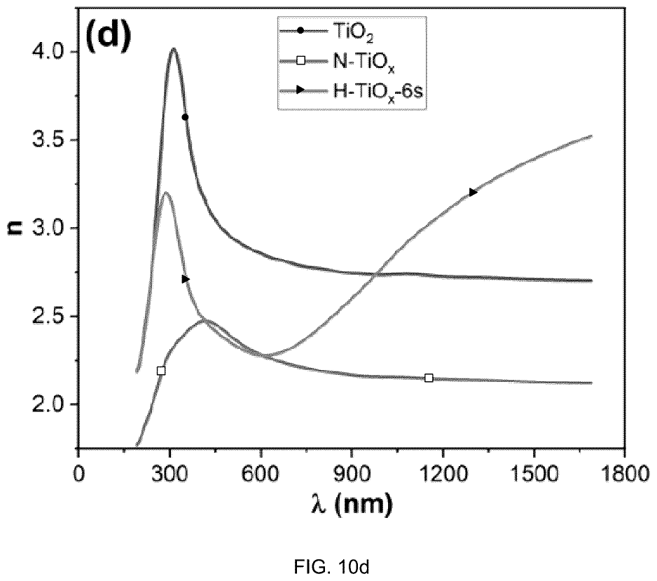

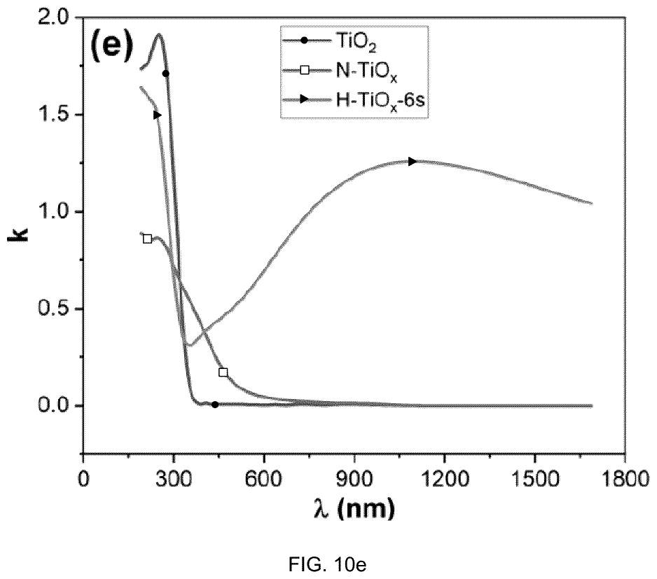

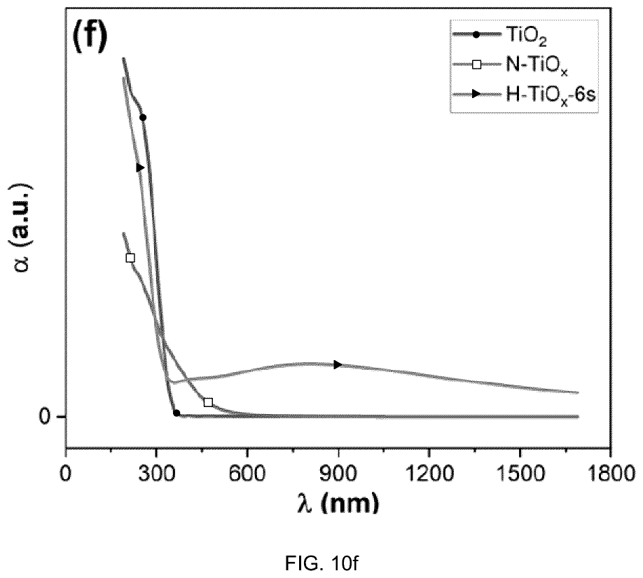

FIGS. 10a-f shows the optical coefficients and absorption spectra of TiO₂, N—TiOₓ, and H—TiOₓ obtained from ellipsometer measurements. The details of the ellipsometer analysis are given in the Experimental Section B. Spectra shows that H—TiOₓ shows the broadest absorption in UV, visible and infrared light regions compared to TiO₂ and N—TiOₓ. The extended absorption gives rise to black colored film. The enhanced absorption below the bandgap energy is indicative of either free charge carrier absorption or absorption caused by intraband gap states. The wide absorption spectrum of H—TiOₓ is because of the presence of trapped charge carriers within the bandgap, which is later identified as Ti³⁺.

From the physical model constructed by the ellipsometry measurements, the optical constants and absorption coefficients were determined as plotted in FIGS. 10a-f, which are the raw data used to measure bandgaps.

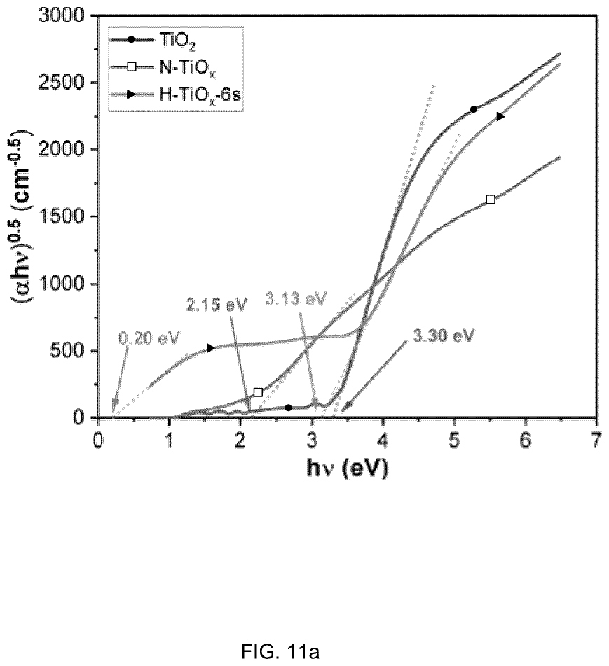

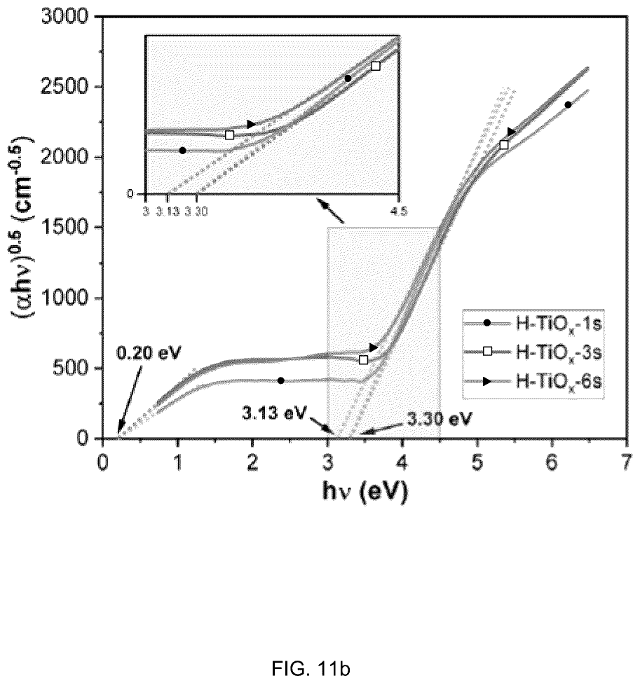

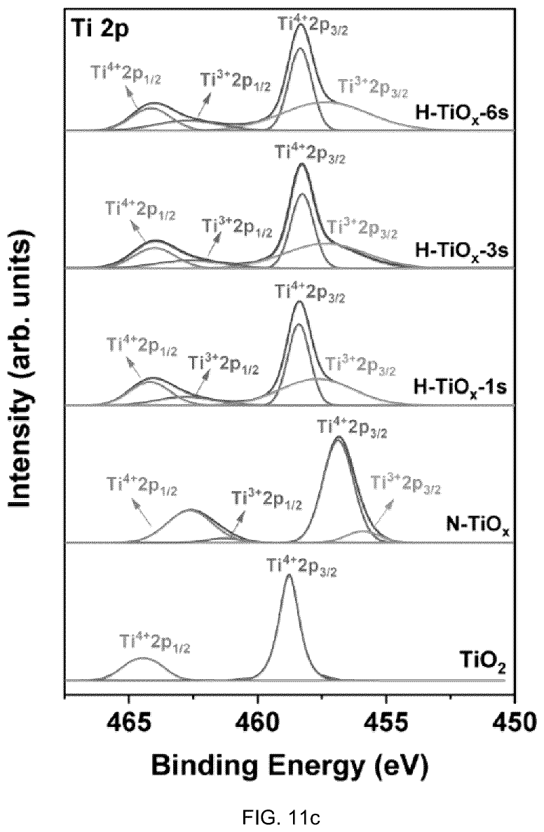

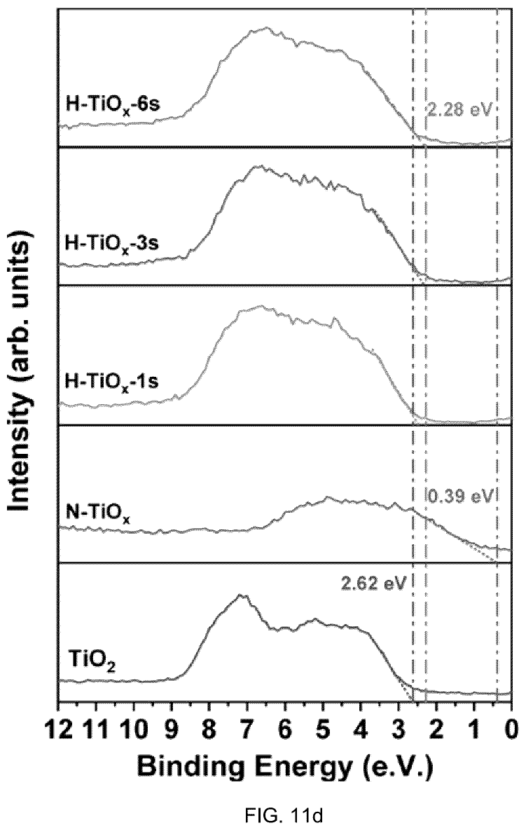

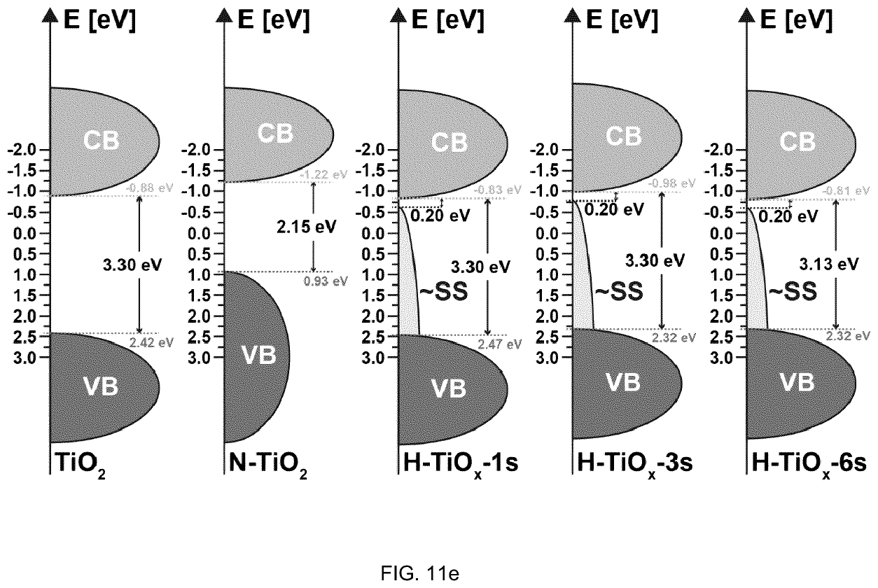

FIG. 11a and FIG. 11b represent the Tauc plots obtained from Elipsometry measurements. Pristine TiO₂ has a bandgap energy of 3.30 eV, as well known. With nitrogen doping, the narrowing of the bandgap from 3.30 eV to 2.15 eV was observed and this is consistent with previous works. For the H—TiOₓ samples, along with the bandgap energy, additional energy levels appeared. This is because of the creation of Ti³⁺ and oxygen vacancies with the H₂ plasma treatment. These defects form shallow trapped states in the bandgap and they can easily be released back to the CB, making this type of defect advantageous for charge transfer due to the increased carrier densities. These shallow states are also responsible for optical absorption in the visible light region.

For calculating the bandgap energies of the films, the Tauc plots were constructed using the absorption coefficients, a, extracted from the optical model of the ellipsometry. The energy-dependent absorption coefficient expressed with the following formula (Eq. 3):

(αhv)^{1/γ}=B(hv−E_{g}) (3)

where h is the plank constant, v is the frequency of the photon, B is a constant, and Eg is the bandgap energy. The factor γ depends on the nature of the electron transition and TiO₂ shows the indirect transition bandgap properties, therefore γ=2 was used for all calculations. The energy-dependent absorption coefficient was plotted with respect to the photon energy hv and Eg as shown in FIGS. 11a-b and the bandgap energies were determined by extrapolating the intersection of the horizontal axis and the curve from linear region.

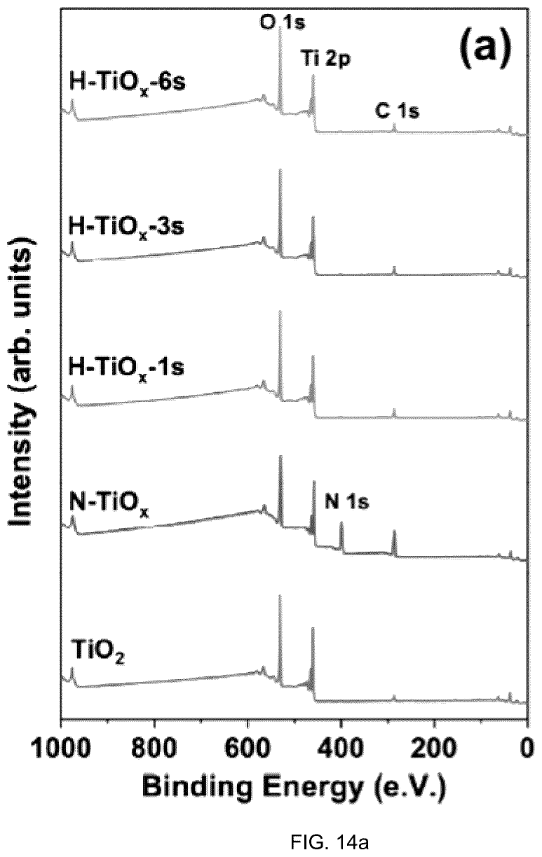

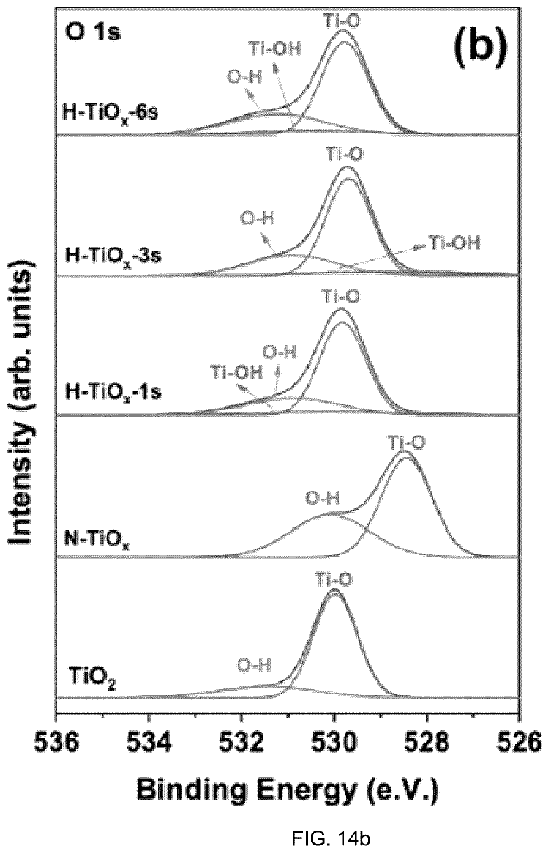

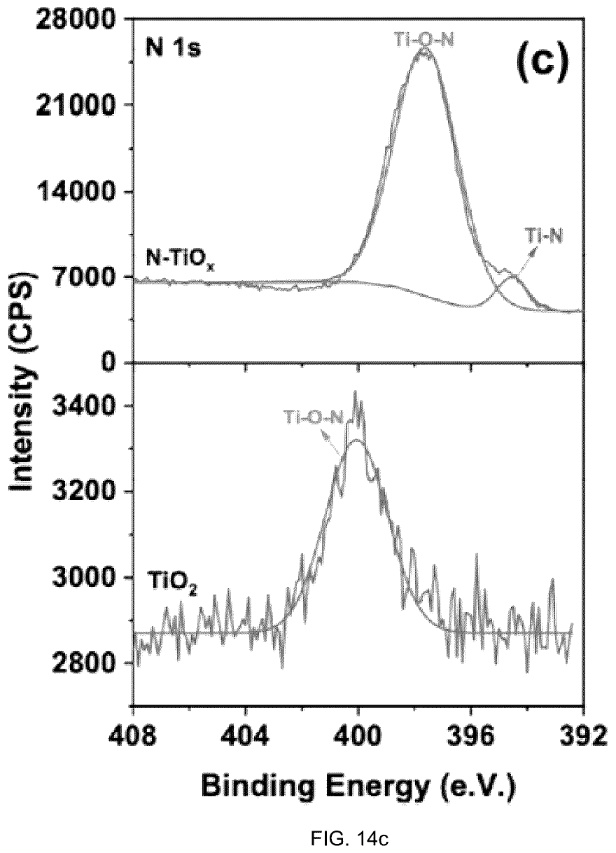

The change in the chemical composition and valance band structure was studied with XPS analysis. The XPS survey spectra (FIG. 14a) clearly show that the surfaces of ALD-grown TiO₂ films are clean, with only a trace amount of C coming from air exposure.

The XPS survey spectra (FIG. 14a) clearly show that the surfaces of ALD-grown TiOₓ films are clean, with only a trace amount of C coming from air exposure. Ti, O, and C elements were found from the survey scan of TiO₂ and H—TiOₓ films. Additionally, the N 1 s peak was observed in N—TiOₓ. Figure S3b shows the O1 s spectra for the TiOₓ films. The center peak that appeared at 530 eV is expected for O²⁻ anions of the TiO₂ structure, i.e. from the Ti⁴⁺—O²⁻ bond, while the peak at 531.6 eV is attributed to hydroxyl groups on the surface of the films. With introducing the N₂ plasma to lead the formation of N—TiOₓ, the Ti—O bond intensity decreased, and adsorbed oxygen intensity increased. This is possibly because of the fact that the incorporation of nitrogen atoms into the films limits the Ti—O bond formation. Additionally, the peaks were shifted from 530 and 531.6 eV to 528.4 and 530 eV, respectively with N₂ plasma exposure. These shifts are because of the formation of Ti—N and Ti—O—N bonds as shown in XPS N 1 s spectrum of N—TiOₓ (FIG. 14c). By H₂ plasma introduction, slight peak shifts were observed to lower binding energies with a new peak corresponding to Ti—OH bond formation.

The Ti 2p XPS spectra of TiO₂, N—TiOₓ, and H—TiOₓ with different H₂ plasma times are given in FIG. 11c. For the TiO₂, the main Ti 2p_{3/2} and Ti 2p_{1/2} peaks were centered at binding energies 458.7 and 464.4 eV, respectively with the ABE value (difference in binding energy) of 5.7 eV, which indicates that these are characteristic Ti⁴⁺—O bonds. When N² plasma was used, the Ti 2p peaks shifted to 456.8 and 462.5 eV, respectively, with a BE negative shift of about 1.9 eV compared with TiO₂. Two additional peaks at 455.8 and 461.3 eV appeared which can be assigned to Ti³⁺ 2p_{3/2} and Ti³⁺ 2p_{1/2}, respectively. These results are also consistent with previous reports. By introducing the H₂ plasma, the Ti⁴⁺2p_{3/2} and Ti⁴+2p_{1/2} peaks appeared at 458.3 and 464 eV, respectively, with a BE negative shift of 0.3 eV compared with TiO₂.

The formation of Ti³⁺ is more dominant in H—TiOₓ films and the area under the Ti³⁺ 2p_{3/2} and Ti³⁺ 2p_{1/2} increased with increasing the H₂ plasma time, which means that Ti³⁺ amount increases as the H₂ exposure time increases to the film. The formation of Ti³⁺ explains the increased absorption in the visible light region and conductivity, as well as the narrowed bandgap with the formation of shallow trap states.

The valance band maxima (VBM) were determined by linearly extrapolating the peaks to the baselines, which gives a band edge position for all samples as shown in FIG. 11d. The VBM of TiO₂ was found at 2.62 eV and with N-doping, the band edge shifted to 0.39 eV. Similarly, with H— doping, VBM rise was observed. With H₂ plasma introduction, the VBM edge shifted maximum to 2.28 eV. The VB shift is common in the presence of lattice disorders.

Based on the ellipsometry and high-resolution VB XPS results, the proposed energy band structure and the DOS (density of states) of TiO₂, N—TiOₓ, and H—TiOₓ with different plasma times are demonstrated in FIG. 11e. With the H₂ plasma treatment, which leads to the formation of Ti³*, oxygen vacancies, and lattice disorder, shallow states appear above and overlap with the VB of TiO₂. This can raise the VBM and result in narrowing the bandgap, therefore enhancing the conductivity.

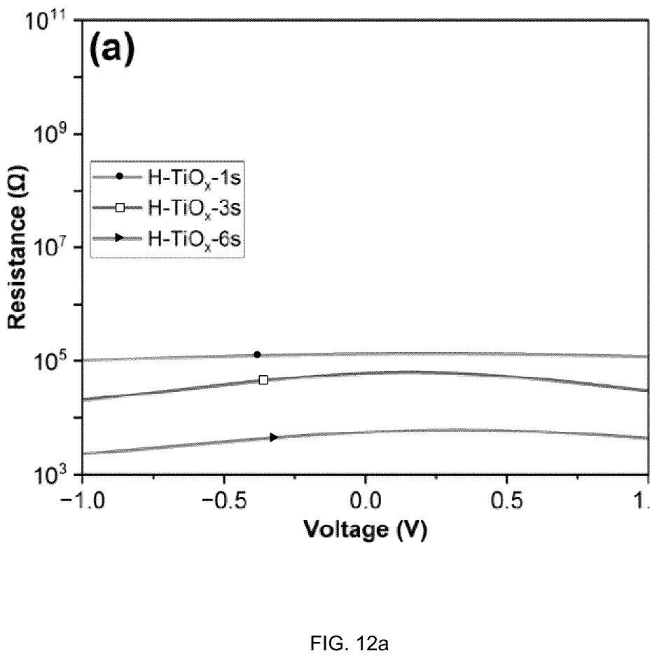

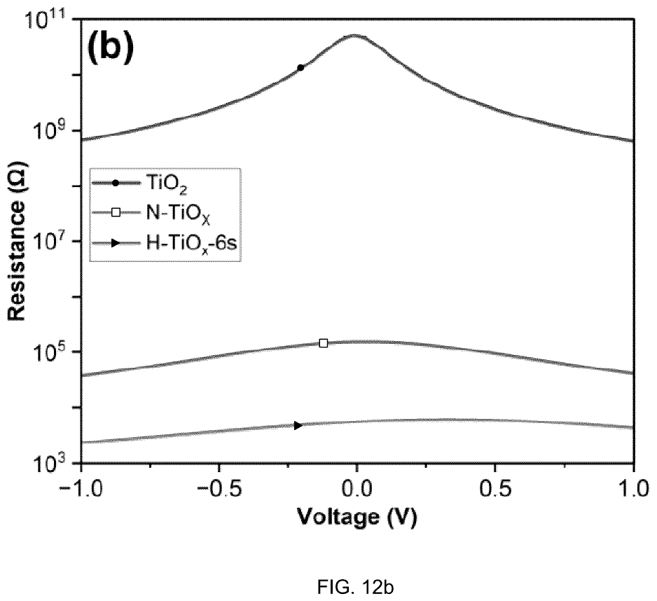

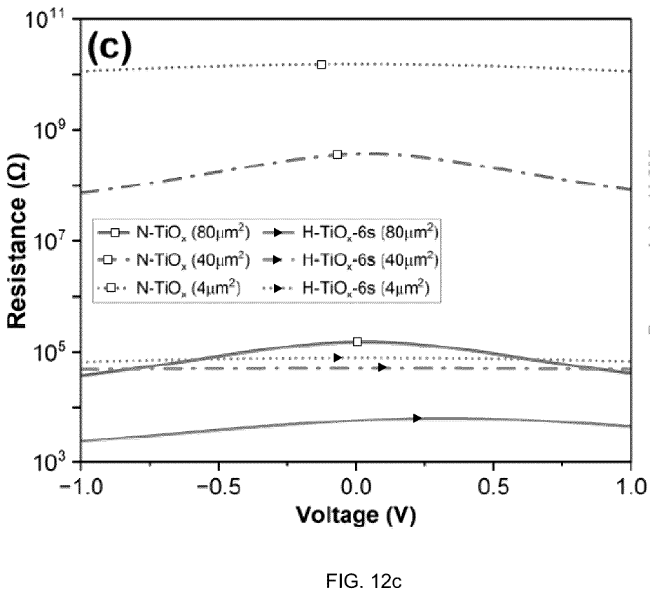

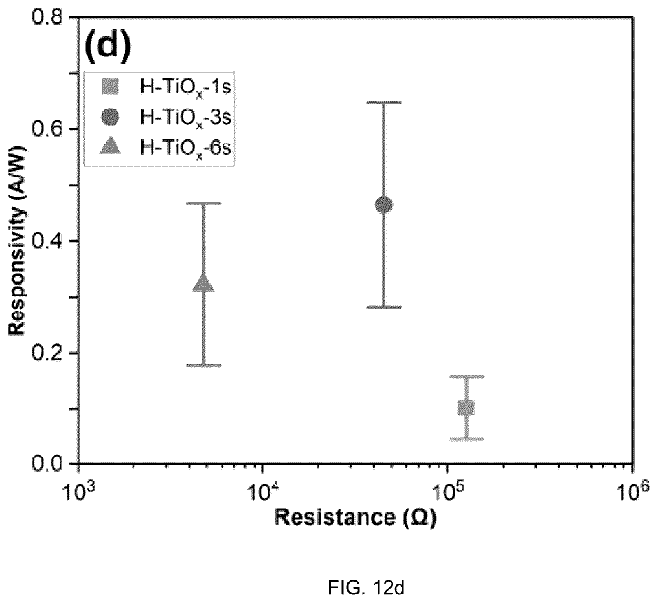

FIG. 12a-b illustrates the voltage-dependent resistance characteristics of TiO₂, N—TiOₓ, and H—TiOₓ diodes. The resistance data reveal distinctive behaviors influenced by the type of doping, highlighting the effectiveness of doping strategies in modifying the electrical properties of the diodes. TiO₂ diodes consistently exhibit the highest resistance levels throughout the voltage range tested, with values spanning from 10¹⁰Ω to 10¹¹Ω. This elevated resistance underscores the limited intrinsic conductivity of TiO₂, which can be attributed to a lower density of charge carriers that impede electron mobility. H—TiOₓ diodes demonstrate significantly lower resistance, maintaining relatively stable values around 10⁴Ω to 10⁵Ω across the entire voltage range. This substantial reduction in resistance, by approximately six orders of magnitude, suggests a profound modification of the electronic structure through hydrogen doping. Hydrogen likely serves to create oxygen vacancies and make shallow trap states associated with Ti³⁺ ions, and enhance charge carrier mobility. This improvement is crucial for applications requiring high-speed electronic switching and reduced energy losses, such as in advanced computing architectures or energy-efficient sensors. N—TiOₓ diodes also exhibit reduced resistance compared to TiO₂ ones but generally display higher resistance levels than H—TiOₓ, ranging approximately from 10⁵Ω to 10⁷Ω. The resistance profile of nitrogen-doped diodes shows a moderate dependency on voltage, indicating that nitrogen introduces electronic states near the valance band. While these states are beneficial, they appear less effective at reducing resistance than hydrogen doping.

FIG. 12c illustrates the resistance characteristics of hydrogen- and nitrogen-doped diodes as a function of pad size. The data reveal significant insights into the interplay between surface area, doping type, and resistance, which is important for optimizing material properties in various applications. For H—TiOₓ diodes, a subtle trend of decreasing resistance with increasing pad size is observed. The smallest pad size (4 μm²) exhibits a resistance of approximately 10⁵Ω. As the pad size increases to 40 μm² and 80 μm², there is a slight drop in resistance, stabilizing around 10³Ω. This behavior underscores the effectiveness of hydrogen doping in maintaining relatively consistent electrical conductivity across different device geometries. The modest decrease in resistance (two orders of magnitude) from the smallest to the largest pad sizes suggests that hydrogen doping effectively creates shallow defect states, while also demonstrating good scalability. N—TiOₓ diodes, on the other hand, display a more pronounced relationship between resistance and pad size. For N—TiOₓ, the resistance is consistently higher across all pad sizes compared to H—TiOₓ, but shows a significant decrease with increasing pad size. At the smallest pad size (4 μm²), the resistance is approximately 10¹⁰Ω, which decreases substantially to around 10⁶Ω for the larger 40 μm² and 80 μm² pads. This behavior suggests that nitrogen doping introduces states that facilitate conductivity, but their effectiveness in promoting conduction is highly dependent on the device dimensions. The distinct resistance-size relationships observed for H—TiOₓ and N—TiOₓ can be attributed to the different mechanisms by which these dopants modify the electronic structure of TiOₓ. Hydrogen likely forms shallow trapped states in the bandgap, leading to enhanced conductivity that remains relatively stable with changing pad size. Nitrogen, conversely, may introduce deeper-level states, resulting in higher overall resistance and a more pronounced size dependency.

The distinct resistance-size relationships observed for H—TiOₓ and N—TiOₓ have significant implications for high-frequency applications, particularly in the context of the cutoff frequency, a critical metric for evaluating the performance of diodes. The cutoff frequency (fc) is inversely proportional to the product of the diode resistance (R) and capacitance (C) shown in Equation (4):

$${f}_{c} = \frac{1}{2 π RC} \qquad ( 4 )$$

where the capacitance for these devices in Equation (5), modeled as parallel-plate capacitors, is determined by:

$$C = \frac{{ε}_{r} {ε}_{0} A}{d} \qquad ( 5 )$$

Here, εᵣ is the relative permittivity of the dielectric material, so is the permittivity of free space, A represents the area of the plates, and d is the distance between them.

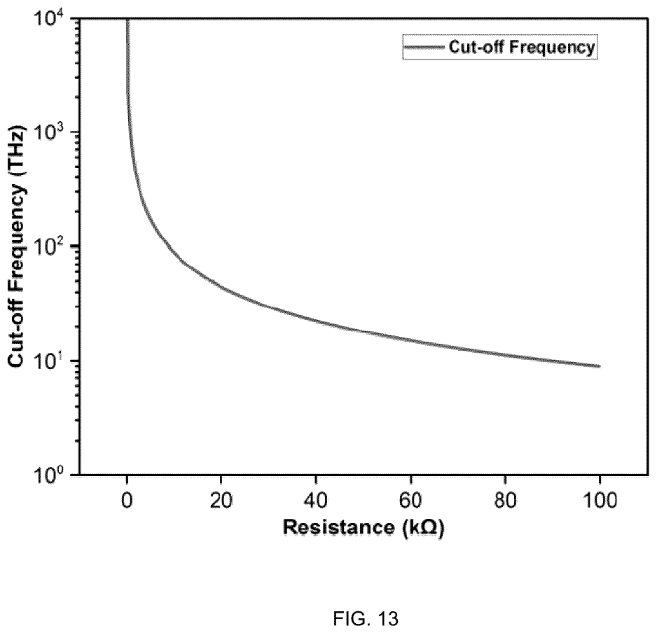

As the size of the diode decreases, maintaining low resistance becomes increasingly relevant for high-performance THz applications. To determine the resistance threshold for terahertz operation, the device was modeled with specific characteristics to ensure accuracy: the area was assumed to be 100 nm², the film thickness was set at 5 nm, and the dielectric constant was taken as 1 F/m. FIG. 13 shows that to ensure effective operation within the terahertz range (above 1 THz), the resistance of the diode should not exceed 100,000Ω. This finding underscores the necessity of minimizing resistance during the design and fabrication of MIM diodes to enhance their suitability for high-frequency applications. In the context of the doping study, the H—TiOₓ diodes show promising characteristics for high-frequency applications. Even at the smallest pad size (4 μm²), the resistance of H—TiOₓ diodes (10⁵Ω) is within the range required for terahertz operation. Moreover, the subtle decrease in resistance with increasing pad size suggests that H—TiOₓ diodes could maintain their high-frequency performance across various device dimensions. Conversely, the N—TiOₓ diodes present challenges for high-frequency applications, particularly at smaller pad sizes. With a resistance of 10¹⁰Ω at 4 μm², N—TiOₓ diodes significantly exceed the resistance threshold for effective terahertz operation. However, the substantial decrease in resistance with increasing pad size indicates that N—TiOₓ diodes might be suitable for high-frequency applications at larger dimensions, where their resistance approaches 10⁶Ω. These findings highlight the importance of considering both doping strategy and device geometry in the design diodes for high-frequency applications. The superior performance of H—TiOₓ diodes across various pad sizes makes them particularly attractive for terahertz applications, especially in scenarios where device miniaturization is crucial. The strong size dependence of N—TiOₓ diodes' resistance suggests that their use in high-frequency applications may be limited to larger device dimensions, or may require additional optimization strategies to reduce resistance at smaller scales.

For the diode performance figure of merit, the responsivity is calculated using the following formula (Eq. 6) from measured IV-curves:

$$Responsivity = ( \frac{{d}^{2} I}{d {V}^{2}} / \frac{dI}{d V} ) \qquad ( 6 )$$

where I and V are the diode current and voltage, respectively. The numerator represents the second derivative of the current with respect to voltage, while the denominator is the product of the first derivative of the current with respect to voltage and twice the change in voltage.

Using equations 1 and 2, the relationship between the cutoff frequency, fc, and diode resistance, R, is plotted in FIG. 13.

FIG. 12d reveals the relationship between hydrogenation time, resistance, and responsivity, highlighting the role of trapped states and oxygen vacancy concentration in H—TiOₓ diodes. The 1 s hydrogenated TiOₓ sample exhibits a high resistance of approximately 10⁵Ω, coupled with a low responsivity of about 0.1 A/W. This behavior can be attributed to insufficient introduction of oxygen vacancies and trapped states, maintaining a high barrier height at the metal-insulator interface. Consequently, electron transport is predominantly governed by Schottky emission, a mechanism characterized by thermionic emission over a barrier. This process contributes minimally to non-linear increases in current with voltage changes, explaining the observed low responsivity.

In contrast, the 3 s hydrogenated TiOₓ sample demonstrates significantly improved performance, with a moderate resistance of around 10⁴Ω and a high responsivity of approximately 0.65 A/W. This enhancement may result from an optimal concentration of oxygen vacancies and trapped states, which effectively lowers the barrier height and facilitates electron transport through mechanisms such as Fowler-Nordheim tunneling and Poole-Frenkel emission. These tunneling processes contribute to higher responsivity, illustrating the critical balance between vacancy concentration and electron transport mechanisms necessary for achieving both lower resistance and higher responsivity.

The 6 s hydrogenated TiOₓ sample, despite exhibiting further reduction in resistance to around 10⁴Ω, shows only a moderate responsivity of approximately 0.4 A/W. This may be attributed to extensive hydrogenation creating a high density of oxygen vacancies and trapped states, which promotes direct tunneling and trap-assisted tunneling mechanisms. While these mechanisms decrease the barrier width and height, thereby enhancing electron transport and reducing resistance, they also introduce numerous trap states. These defects likely trap and recombine carriers, leading to only moderate increases in responsivity.

### Experimental Section B

According to a present embodiment, a fabrication process for another MIM diode is now described.

The diodes were fabricated on 1 cm by 1 cm SiO₂ wafers. A layer of positive photoresist S1805 was spin-coated onto the SiO₂ substrates. A Heidelberg MLA was then used to pattern the first electrode with a device area. The sample was subsequently developed in MF-319 for 45 min to remove unexposed areas of the photoresist. For the Pt/TiOₓ/Al diodes, the bottom Pt electrodes with 80 nm thickness were deposited using an E-beam evaporation system with a base pressure set to 4×10⁻⁶ Torr and a 3 angstrom/s deposition rate. The photoresist was lifted off, forming the bottom Pt electrode of the MIM diode.

To deposit the insulator in the Pt/TiO₂/Al diodes, 400 cycles of insulators were deposited at 250 °C using remote PAALD with a base pressure below 1.33×10⁻⁴ Pa. In this process, three precursors were used: TTIP, 02/N₂, and Ar as the inert gas. The vacuum chamber was first purged with Ar for 3 min to stabilize the chamber pressure and temperature. TIIP bubbled with argon was used to dose the substrate for 2 s at a pressure of 10.6 Pa, and the precursor line was then purged with Ar for 3 s at a pressure of 2 Pa. For TiO₂ films, a flow of O₂ was then stabilized for 500 ms before generating a plasma via radio frequency (RF) with a power of 300 W at a pressure of 2 Pa. The substrate was exposed to the O₂ plasma for 3 s and then purged with Ar for 2 s at a pressure of 10.6 Pa.

To deposit the Al top contact, the same processes that were used to deposit the bottom contact were repeated, with a few changes in the second UV exposure. The bottom Pt contact on the sample was aligned with another mask and exposed. Reactive ion etching was used to remove any oxidant on top of the electrodes.

A similar process was used to fabricate the Pt/H—TiOₓ/Al, Pt/N—TiOₓ/Al diodes. For the H—TiOₓ, 400 PAALD cycles were used with H₂ plasma, except the plasma time changed to 1, 3, and 6 seconds respectively. In this embodiment of 400 cycles, each cycle can use the same plasma time. Alternately different cycles can use different plasma times. For example, 100 cycles at 1 s plasma time, then 300 cycles at 6 s plasma time. For the N—TiOₓ, 400 cycles were employed using N₂ plasma. The only sources of oxygen were the TIIP and residual water vapor in the vacuum chamber, with a pressure range of 1.3×10⁻⁴ to 1.3×10⁻⁵ Pa. The N₂ plasma flow was stabilized for 500 ms, and RF plasma was generated with a power of 300 W. The substrates were exposed at a pressure of 2 Pa for 3 s, followed by Ar purging for 2 s at a pressure of 10.6 Pa.

Films were deposited on glass substrates that were 1 cm by 1 cm and 0.5 mm thick for absorption measurements. Films for ellipsometry and XPS measurements were deposited on silicon substrates (100 orientation) that were 1 cm by 1 cm and 330 to 432 μm thick. A Woollam M-2000 DI ellipsometer with a wavelength range of 200-1800 nm was used to measure the thicknesses of undoped and doped TiO₂ films. XPS (VG Scientific ESCALAB 250) was performed on the surface of the films using Al Kα X-ray source. XPS analyses were conducted with OriginPro 2021b, employing the Shirley XPS baseline and Gaussian fitting techniques.

A Keithley 4200-SCS semiconductor characterization system connected to a probe station was used to measure the I-V properties.

Following is a summary of the process step sequence to fabricate the novel MIM diode, according to the present embodiment.

### A) Substrate Preparation

Material: SiO₂ wafers (1 cm×1 cm)
Cleaning: Clean the SiO₂ wafers using a suitable solvent (e.g., acetone, ethanol) to remove any contaminants.
Photoresist Application: Spin-coat positive photoresist (S1805) onto the SiO₂ substrates.
Spin Coating Parameters: Spin at 3000 rpm for 30 seconds.
UV Lithography: Use UV lithography to define the pattern for the bottom electrode.
Development: Develop the sample in MF-319 developer for 45 minutes to remove unexposed photoresist.

### B) Bottom Electrode Deposition (Pt)

Material: Platinum (Pt)
Deposition Method: Electron beam (E-beam) evaporation.
Base Pressure: 4×10⁻⁶ Torr
Deposition Rate: 3 Å/s
Film Thickness: 80 nm
Lift-off: Remove the photoresist to form the bottom electrode pattern using PG Remover.

### C) Insulator Layer Deposition (H—TiOₓ)

Material: H—TiOₓ for hydrogen doping.
Method: Plasma-Assisted Atomic Layer Deposition (PAALD).
Parameters for H—TiOₓ:
Precursor: Titanium isopropoxide (TTIP)
Hydrogenation: Use H₂ plasma instead of O₂.
Hydrogen Plasma Time: 1 s, 3 s, or 6 s depending on desired doping level.
Film Thickness: ~400 cycles.
Temperature: 250 °C
Plasma Power: 300 W
Base Pressure: <1.33×10⁻⁴ Pa
Purge Time (Min): 2 seconds with Ar at 10.6 Pa.
Precursor Dosage: 2 seconds at 10.6 Pa.

### D) Top Electrode Deposition (Al)

Material: Aluminum (Al)
Deposition Method: Electron beam (E-beam) evaporation.
Thickness: 80 nm
Deposition Rate: 3 Å/s
UV Lithography: Align a second mask to define the top electrode. Diode structure between 4 um2 to 100 um2 completed.
Lift-off: Remove the photoresist to form the top electrode pattern using PG Remover.

In the present embodiments of the MIM diode, Pt and Al are used as the bottom and top electrodes, but other combinations of metals can be used instead. All that is required is that the selected metals have a significant difference in work functions, such as at least 0.5 eV to achieve asymmetric diodes. Alternate electrode pairings which can be used instead of Pt and Al include: Pt (5.3-5.65 eV) and Ti (3.7-4.33 eV); Au (4.8-5.28 eV) and Al (4.2-4.28 eV); Ni (4.9-5.35 eV) and Al (4.2-4.28 eV); Pd (5.0-5.12 eV) and Ti (3.7-4.33 eV) and Ag (4.26-4.7 eV) and Ti (3.7-4.33 eV). In alternate embodiments, the MIM diodes can be formed with 2 electrodes having a work function difference ranging between 0.1-2 eV or 0-2 eV. More specifically there are applications at the terahertz level which can benefit from electrodes having identical work functions, thereby resulting in a work function difference of 0.

In the above described fabrication process of the present embodiment, hydrogen plasma times of 1 s, 3 s, or 6 s are used. Longer hydrogen plasma times are beneficial, and is presently constrained by plasma stability as maintaining plasma beyond a specific time, such as 15 s, poses a technical challenge.

In the above described fabrication process of the present embodiment, 400 deposition cycles are used, which yields a roughly 5 nm thickness layer. More deposition cycles can be used in alternate embodiments, but beyond 15 nm, resistance of the film increases significantly.

It is noted that the temperature can be varied from 250 degrees Celsius up to 500 degrees Celsius during the insulator deposition process, which will result in the insulator to have fewer defects. Accordingly the temperature can be selected based on the desired application for the MIM diode. Similarly, the plasma power can be varied between 200 W and 500 W where the higher range of power will increase the defects in the insulator structure. Again, this allows for customization of the level of defects in the insulator structure, and in combination with temperature control this fabrication process can be tailored to adapt to fabrication systems which may have practical functional limits.

In the above described fabrication process of the present embodiment, the precursor dosage of 2 seconds at 10.6 Pa can be varied in differing combinations, as long as the process can maintain an adequate surface coverage of the precursor during each pulse. For example, at higher pressures, the same amount of precursor can often saturate the surface more quickly, potentially allowing for a shorter dosage time. Conversely, at lower pressures, a longer pulse is needed to achieve the same coverage.

Δn alternate PAALD process can be used in accordance with alternate embodiments, to fabricate TiOₓ films with various doping profiles. All procedures utilized 400 deposition cycles to ensure consistent film thickness. The process parameters are given Table 3.

TABLE 3

| | | | | Plasma | Plasma | Number |
|---|---|---|---|---|---|---|
| | O₂ | H₂ | N₂ | time (H₂) | time (N₂) | of |
| Procedure | (sccm) | (sccm) | (sccm) | (s) | (s) | Cycles |
| 1 | 0 | 50 | 0 | 1 | 0 | 600 |
| 2 | 0 | 50 | 0 | 3 | 0 | 600 |
| 3 | 0 | 50 | 0 | 6 | 0 | 600 |
| N—TiOₓ | 0 | 0 | 50 | 0 | 3 | 600 |
| TiO₂ | 60 | 0 | 0 | 0 | 0 | 600 |

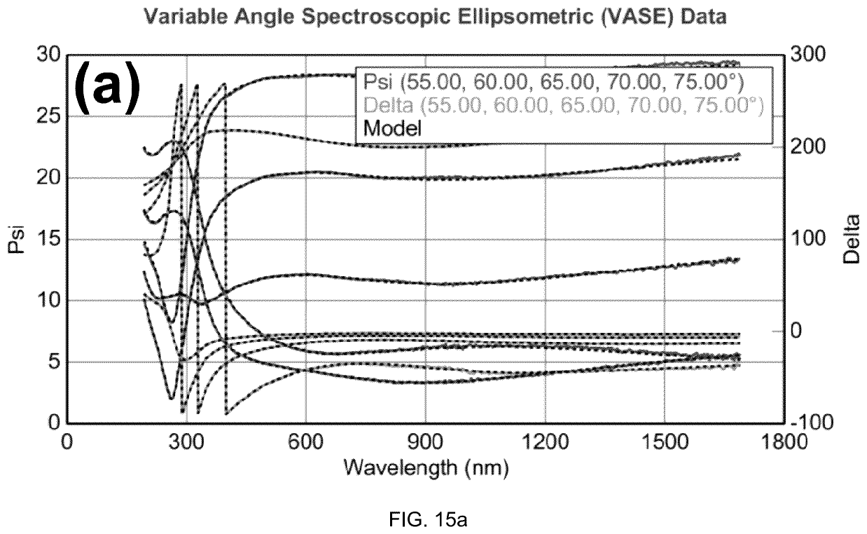

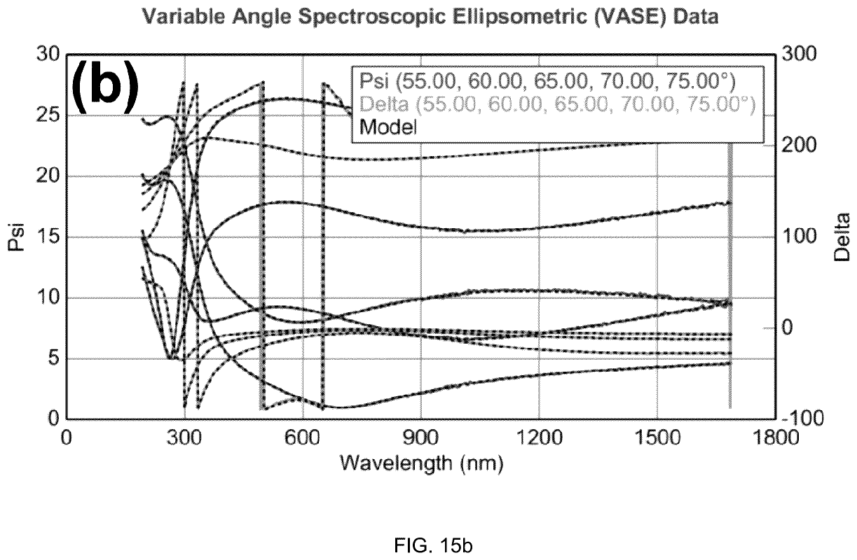

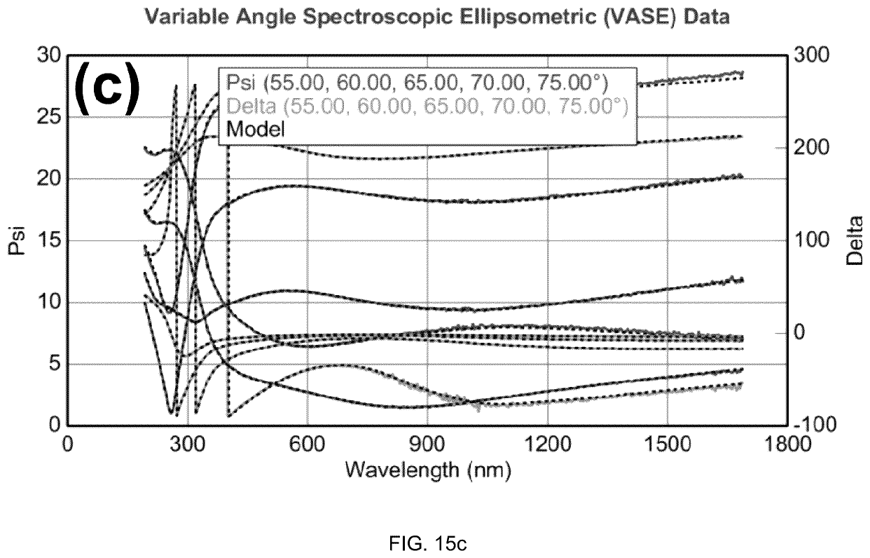

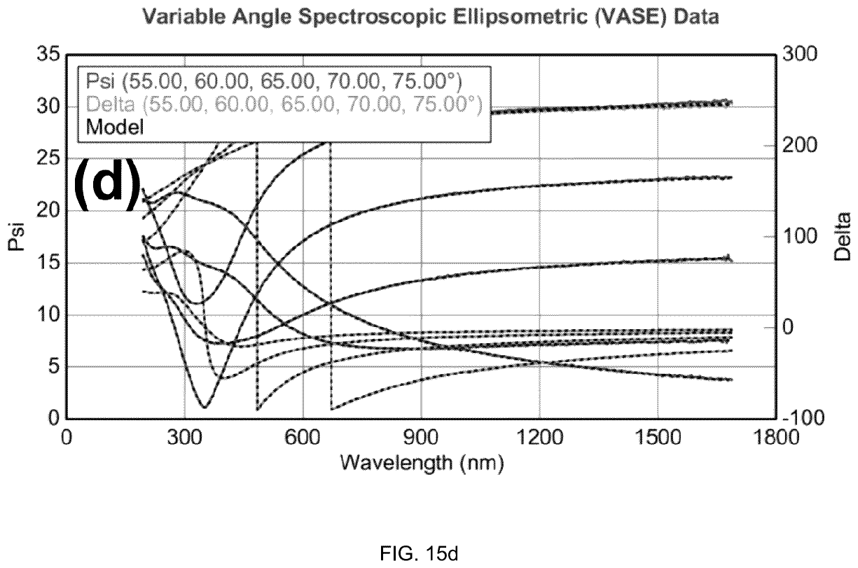

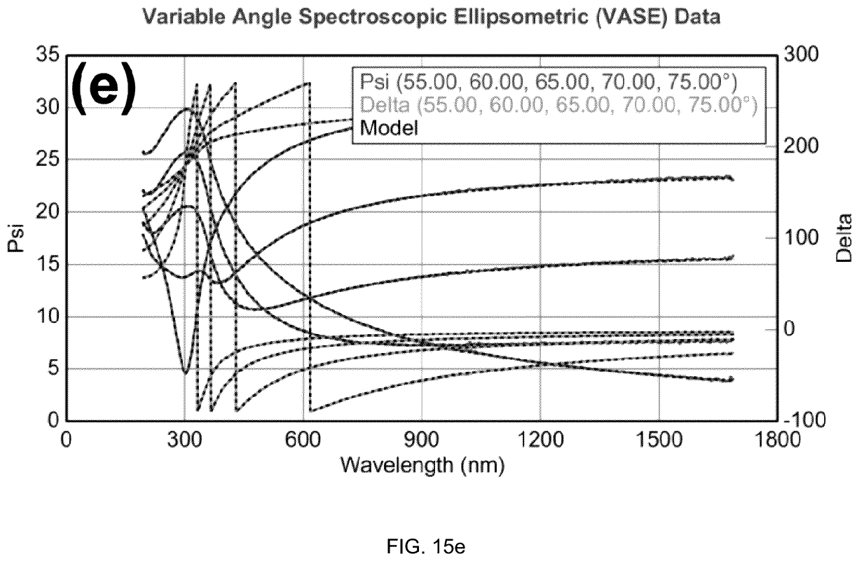

The raw and modeled data from the ellipsometer for different fabricated films are shown in FIGS. 15a-e. More specifically, FIGS. 15a-e show Variable Angle Spectroscopic Ellipsometric (VASE) data and modeled B-spline fit for H—TiOₓ-1 s (FIG. 15a), H—TiOₓ-3 s (FIG. 15b), H—TiOₓ-6 s (FIG. 15c), N—TiOₓ (FIG. 15d) and TiO₂ (FIG. 15e) films. This supplementary data supports the experimental findings and underlying mechanisms relevant to the presently described embodiments.

Overall, the present embodiments of the MIM diode includes a defect-engineered insulator structure: In an embodiment, it involves an in-situ doping method using hydrogen plasma at temperatures between 100-400 °C during the atomic layer deposition (ALD) process in an oxygen-free environment. The precise control of hydrogen plasma exposure time, ranging from 1 to 60 seconds, allows for the introduction of hydrogen dopants into the insulator material, forming specific defect structures that enhance electron tunneling at terahertz frequencies.

In this embodiment the insulator within this structure has a precisely controlled thickness, ranging from 0.1 nm to 100 nm, and can cover an area between 1 nm² and 100,000,000 nm². This range allows for flexibility in design, catering to various performance requirements for terahertz applications.

The presently described investigation on in situ H—TiOₓ for MIM diodes has yielded significant insights into enhancing diode performance for high-frequency applications. Through a novel PAALD technique, the present embodiments have demonstrated the first application of H—TiOₓ in diodes. Hydrogen doping significantly reduces diode resistance, with H—TiOₓ diodes exhibiting resistance values of 10⁴-10⁵Ω, compared to 10¹⁰-10¹Ω for TiO₂ diodes. This reduction is crucial for high-frequency applications, particularly in the terahertz range. The resistance of H—TiOₓ diodes shows minimal dependence on pad size, indicating good scalability. In contrast, N—TiOₓ diodes exhibit higher resistance (10⁵-10⁷Ω) and stronger size dependency, suggesting that nitrogen doping may be less effective for certain high-frequency applications. This investigation reveals a critical relationship between hydrogenation time, oxygen vacancy concentration, and diode characteristics. The 3 s hydrogenated TiOₓ sample achieved an optimal balance, demonstrating both low resistance (~10⁴Ω) and high responsivity (0.65 A/W). The improved performance is attributed to the creation of shallow trapped states and oxygen vacancies, which modify the electronic structure and enhance charge carrier mobility. These embodiments presents a novel approach to simultaneously achieving lower resistance and higher responsivity in metal-single insulator-metal diodes through careful dopant engineering. The demonstrated ability to tailor diode characteristics through controlled doping processes has potential applications in various fields, including advanced computing architectures, energy-efficient sensors, and terahertz technologies. Future research opportunities include further optimization of the hydrogenation process, investigation of combined doping strategies, exploration of long-term stability, development of precise control mechanisms for the PAALD process, and integration of H—TiOₓ diodes into with antenna for real-world validation. In conclusion, the presently described in situ H—TiOₓ MIM diodes represents a significant advancement in high-frequency electronics. By elucidating the relationships between doping strategies, material properties, and device performance, the inventors have laid the groundwork for future innovations in diode design and fabrication, potentially leading to next-generation technologies for terahertz and beyond.

This disclosure has described specific AP-CVD and PAALD fabrication processes for forming the insulating layer of MIM diodes, with the aim of introducing intrinsic defects in a controlled manner within its structure. Both fabrication methods, share the common feature where controlled defects are engineered by exposing the material to gases under heat, allowing for the adjustment of electrical properties in the oxide films as they are being formed. The PEALD fabrication process on the other hand generally produces defect-free films because it operates in a low-pressure vacuum environment.

According to alternate variations of the embodiment, after doping one insulator layer, additional insulator layers can be stacked on top, creating various metal-hydrogen-doped-insulator-metal (M/H—In/M) structures. These offer enhanced tunability and improved performance for terahertz frequency applications.

The benefit of the above described stacked insulator approach is to overcome a limitation where layers exceeding about 10 nm suffer from lower tunneling efficiency, increasing resistance and reducing the responsiveness of the diode. Using stacked insulators on the other hand offers better control over rectification by enhancing nonlinearity and improving the responsivity-to-resistance ratio. It should be noted that in the stacked insulator embodiments, a 0.5 eV work function difference still applies. However, the dielectric properties of each layer may affect the diode's asymmetry and performance, so further tuning might be needed based on layer interactions. By layering insulators with different band gaps and dielectric properties, the diode's electrical response can be adjusted without thickening individual layers beyond a point where the above deficiencies are observed, which would hinder performance by limiting electron transmission. By example in one of the present experiments, it was discussed that the thickness of one insulating layer beyond 15 nm will exhibit significantly higher resistance which is undesirable.

Following is a description of Metal-Insulator-Insulator-Metal (MIIM) tunnel diode embodiments utilizing hydrogen-doped titanium dioxide (for example 5 nm H—TiO₂) as the primary insulating layer combined with various secondary insulators. These MIM diode embodiments demonstrate a breakthrough in diode performance, achieving unprecedented responsivity values while maintaining remarkably low resistance—an important balance for high-frequency electronics and energy harvesting applications. Through systematic defect engineering and bandgap manipulation, the fabricated devices overcome the traditional trade-off between responsivity and resistance that has historically limited MIM diode technology.

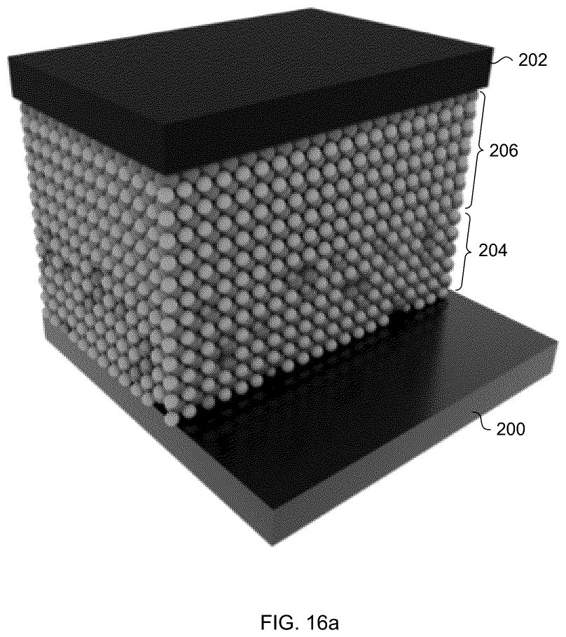

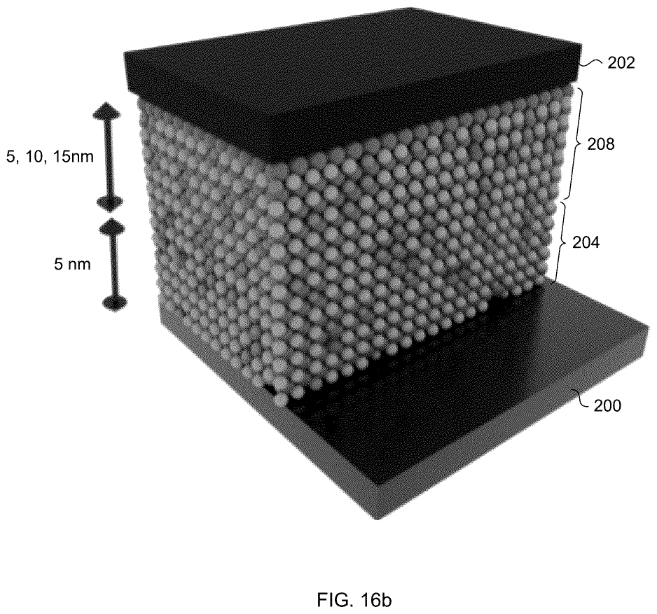

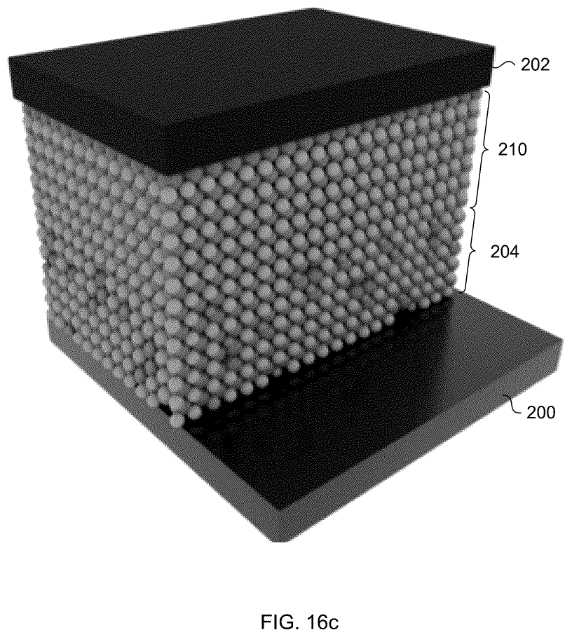

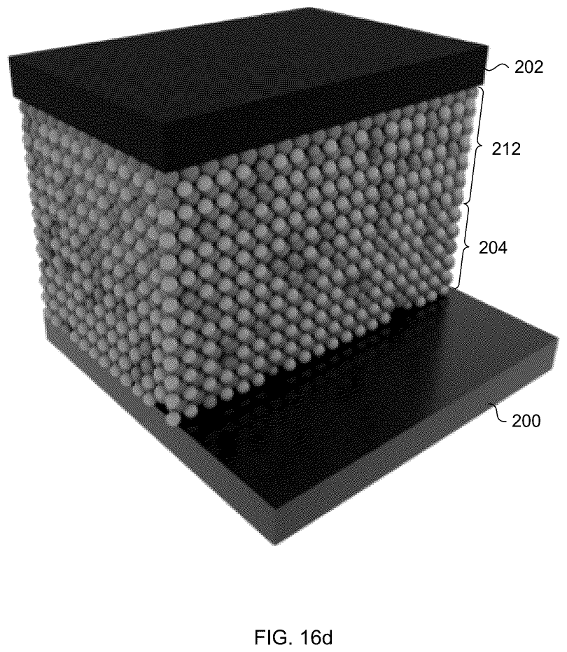

FIGS. 16a, 16b, 16c and 16d show different MIIM diode devices, according to the present embodiments.

FIG. 16a is a graphical representation of the device structure of a MIIM diode consisting of Pt/H—TiO₂/TiO₂/Al. Pt forms the bottom electrode 200, Al forms the top electrode 202, and in between the two electrodes is a dual insulating layer of H—TiO₂ 204 adjacent to the Pt electrode and TiO₂ 206 adjacent to the Al electrode.

The H—TiO₂/TiO₂ bilayer structure of this embodiment represents a baseline configuration, combining a low-resistance hydrogen-doped titanium dioxide layer with an undoped titanium dioxide secondary insulator. This structure leverages the resistance-reducing properties of hydrogen doping, which introduces oxygen vacancies and Ti³⁺ states that dramatically lower the device resistance from 10¹⁰-10¹¹Ω to 10⁴-10⁵Ω. When paired with a stoichiometric TiO₂ second layer, devices with 1 nm thickness achieved approximately 250 A/W responsivity at a resistance near 10⁶Ω, while 10 nm configurations reached over 10⁹Ω with minimal responsivity. This demonstrates the fundamental challenge of the thickness-dependent trade-off: thicker layers increase resistance exponentially while providing limited improvement in device performance. The undoped bilayer serves as an important control, establishing baseline performance metrics against which nitrogen-doped variants can be evaluated.

FIG. 16b is a graphical representation of the device structure of a MIIM diode consisting of Pt/H—TiO₂/N-TiO₂/Al. Pt forms the bottom electrode 200, Al forms the top electrode 202, and in between the two electrodes is a dual insulating layer of H—TiO₂ 204 adjacent to the Pt electrode and N—TiO₂ 208 adjacent to the Al electrode.

The Hydrogen-Doped Titanium Dioxide with Nitrogen-Doped Titanium Dioxide (H—TiO₂/N—TiO₂) bilayer structure represents the optimum device architecture, delivering record-breaking performance that fundamentally advances MUM diode technology. This configuration achieved a peak responsivity of 1200 A/W—more than 60 times higher than the theoretical Schottky limit of 19.4 A/W at room temperature and over 30 times higher than the previous record of 36.8 A/W. The incorporation of nitrogen into the secondary titanium dioxide layer introduces N2p states within the bandgap, creating trap sites that enable multiple advantageous conduction mechanisms including trap-assisted tunneling (TAT) and Poole-Frenkel (PF) emission. Devices fabricated with 1 nm N—TiO₂ thickness exhibited resistance values around 10⁶Ω while maintaining responsivity near 300 A/W, representing excellent performance for practical applications. Remarkably, the 10 nm N—TiO₂ variant achieved the unprecedented 1200 A/W responsivity at a resistance of approximately 3×10⁷Ω—significantly lower than undoped counterparts at similar thicknesses. This embodiment demonstrates that strategic defect engineering can simultaneously enhance responsivity and manage resistance, breaking free from the traditional constraints that have limited tunnel diode development.

FIG. 16c is a graphical representation of the device structure of a MIM diode consisting of Pt/H—TiO₂/Al₂O₃/Al. Pt forms the bottom electrode 200, Al forms the top electrode 202, and in between the two electrodes is a dual insulating layer of H—TiO₂ 204 adjacent to the Pt electrode and Al₂O₃ 210 adjacent to the Al electrode.

The Hydrogen-Doped Titanium Dioxide with Aluminum Oxide (H—TiO₂/Al₂O₃) heterostructure uses aluminum oxide as the secondary insulator, offering a different bandgap and dielectric constant compared to titanium dioxide-based layers. Aluminum oxide possesses a wider bandgap (~6-9 eV) compared to TiO₂ (~3.2 eV), creating a pronounced step in the conduction band that theoretically should promote asymmetric tunneling. However, experimental results from this configuration demonstrated relatively modest performance. The 1 nm Al₂O₃ devices exhibited resistance near 10⁷Ω with minimal responsivity, while 10 nm configurations showed resistance exceeding 10⁹Ω with negligible responsivity enhancement. The undoped nature of the Al₂O₃ layer means it lacks the beneficial trap states that enable enhanced conduction mechanisms. While the stepped barrier does provide some structural asymmetry, the absence of defect-mediated transport pathways limits the overall device performance compared to nitrogen-doped variants.

FIG. 16d is a graphical representation of the device structure of a MIIM diode consisting of Pt/H—TiO₂/N-Al₂O₃/Al. Pt forms the bottom electrode 200, Al forms the top electrode 202, and in between the two electrodes is a dual insulating layer of H—TiO₂ 204 adjacent to the Pt electrode and N-Al₂O₃ 212 adjacent to the Al electrode.

The Hydrogen-Doped Titanium Dioxide with Nitrogen-Doped Aluminum Oxide (H—TiO₂/N—Al₂O₃) structure introduces nitrogen doping into the aluminum oxide secondary layer, aiming to combine the advantageous stepped barrier of the Al₂O₃ heterostructure of FIG. 16c with the trap-assisted conduction mechanisms enabled by nitrogen defects. Nitrogen incorporation at approximately 10-12 atomic percent creates N2p states that narrow the effective bandgap and provide intermediate energy levels for electron transport. Devices with 1 nm N—Al₂O₃ thickness achieved extremely low resistance around 150Ω, though this came at the cost of reduced responsivity compared to N—TiO₂ variants. The 10 nm N—Al₂O₃ configuration demonstrated improved balance, with resistance around 100Ω and responsivity approaching 50 A/W. While these results surpass the Schottky limit, they fall short of the performance achieved by N—TiO₂-based devices. The different electronic structure of N—Al₂O₃ compared to N—TiO₂-including different trap energy levels and density of states-likely contributes to the reduced responsivity despite the ultra-low resistance values.

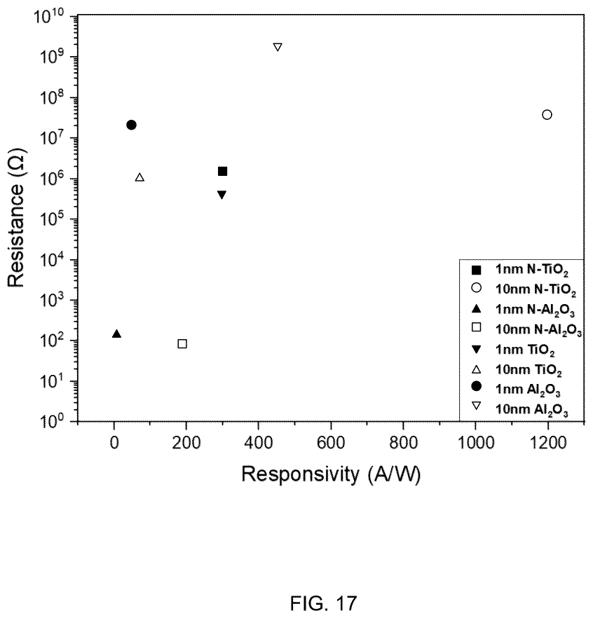

FIG. 17 is a plot of Resistance vs Responsivity measurements taken by an I-V characterization tool for the dual insulating layer MIIM diodes described above where the H—TiO₂ primary insulating layer is fixed at 5 nm. Different thicknesses and corresponding measurements for the secondary insulating layer of N—TiO₂, N—Al₂O₃, TiO₂ and Al₂O₃ are shown.

It is noted that for the previous embodiments of FIGS. 16b and 16d, the dual insulating layer have been tested for combined thicknesses between 10 nm and 20 nm. However, the combined thickness can be up to 100 nm for alternate embodiments.

Following is a discussion of relevant characteristics of the dual insulating layer MIIM diodes which impact tunnel diode performance.

The most significant achievement of this research is the demonstration of a 1200 A/W responsivity in the H—TiO₂/N—TiO₂ device architecture. This value represents a paradigm shift in tunnel diode performance, exceeding the Schottky limit by more than 60-fold and surpassing all previously reported MIM and MIM diode responsivities by over 30-fold. This breakthrough was achieved through the synergistic combination of several factors: (1) the stepped bilayer barrier structure that creates asymmetric tunneling pathways, (2) nitrogen-induced trap states that enable trap-assisted tunneling and Poole-Frenkel emission, and (3) hydrogen-induced oxygen vacancies that provide additional conduction channels. The achievement demonstrates that quantum tunneling diodes are not fundamentally constrained by the thermal limits that govern Schottky diodes, opening new possibilities for high-sensitivity detectors and efficient energy harvesting systems.

The demonstration of a 1200 A/W responsivity in the H—TiO₂/N—TiO₂ device embodiment architecture is significant. This value represents a paradigm shift in tunnel diode performance, exceeding the Schottky limit by more than 60-fold and surpassing all previously reported MIM and MIM diode responsivities by over 30-fold. This breakthrough was achieved through the synergistic combination of several factors: (1) the stepped bilayer barrier structure that creates asymmetric tunneling pathways, (2) nitrogen-induced trap states that enable trap-assisted tunneling and Poole-Frenkel emission, and (3) hydrogen-induced oxygen vacancies that provide additional conduction channels. The achievement demonstrates that quantum tunneling diodes are not fundamentally constrained by the thermal limits that govern Schottky diodes, opening new possibilities for high-sensitivity detectors and efficient energy harvesting systems.

Equally important as the high responsivity is the successful management of device resistance, which directly impacts the RC time constant and determines high-frequency performance. Traditional approaches to increasing responsivity—such as using thicker insulators or more complex structures—typically result in prohibitively high resistance that limits practical applications. The presently described embodiments overcomes this limitation through the strategic use of H—TiO₂ as the primary layer. The hydrogen doping reduces the base resistance by 6-7 orders of magnitude compared to stoichiometric TiO₂, providing a low-resistance foundation that maintains acceptable impedance even with performance-enhancing secondary layers. The optimum H—TiO₂/N—TiO₂ device achieved its record 1200 A/W responsivity at approximately 3×10⁷Ω—remarkably low for such high performance. Even more impressive, the 1 nm N—TiO₂ variant delivered 300 A/W at just 10⁶Ω. The N—Al₂O₃-based devices pushed resistance management to the extreme, achieving values as low as 100-150Ω while maintaining responsivities that exceed the Schottky limit, though at lower absolute values than N—TiO₂.

The development of the dual insulating layer embodiments reveals distinct thickness-dependent trends that provide insight into the underlying physics and design principles for optimizing MIM diodes. For undoped structures (TiO₂ and Al₂O₃), increasing thickness from 1 nm to 10 nm results in exponential increases in resistance—from 10⁶Ω to 10⁹-10¹⁰Ω—with minimal responsivity enhancement, confirming that simple barrier thickening is not an effective strategy. In stark contrast, nitrogen-doped structures exhibit dramatically different behavior. For H—TiO₂/N—TiO₂ devices, the 10 nm configuration actually delivers the highest responsivity (1200 A/W) despite having higher resistance than the 1 nm variant (3×10⁷Ω vs 10⁶Ω). This suggests that the thicker N—TiO₂ layer provides more trap states for defect-mediated conduction or more favorable barrier shaping for asymmetric tunneling. The H—TiO₂/N—Al₂O₃ system shows similar trends but with smaller absolute values. These findings indicate that nitrogen-doped layers can effectively leverage increased thickness to enhance performance, whereas undoped layers simply increase resistance without commensurate benefits.

The comparative analysis across different material systems reveals for future device design. N—TiO₂ clearly emerges as the superior secondary insulator for achieving ultra-high responsivity, likely due to its electronic structure, trap state characteristics, and favorable conduction band alignment with H—TiO₂. The similar crystal structures of TiO₂ and H—TiO₂ may also reduce interfacial defects and promote more coherent electron transport. N—Al₂O₃, while delivering impressive ultra-low resistance, produces lower responsivity values—suggesting that the wider bandgap and different defect chemistry of aluminum oxide create less favorable conditions for the asymmetric, trap-mediated conduction mechanisms that drive high responsivity. The undoped variants (TiO₂ and Al₂O₃) consistently underperform their nitrogen-doped counterparts, confirming that defect engineering through nitrogen incorporation achieves performance beyond conventional limits. This systematic comparison establishes clear materials selection guidelines for future high-performance tunnel diode development.

The exceptional performance of these devices arises from carefully engineered asymmetric conduction mechanisms that differ fundamentally in forward and reverse bias conditions. Under forward bias, the optimum H—TiO₂/N—TiO₂ devices exhibit conduction dominated by Poole-Frenkel emission and trap-assisted tunneling, where electrons utilize nitrogen-induced trap states as intermediate stepping stones through the barrier. This defect-mediated transport dramatically enhances current flow compared to direct tunneling. The stepped bilayer structure further amplifies this effect: under sufficient forward bias, electrons effectively tunnel through only the single N—TiO₂ layer rather than the full bilayer thickness, significantly increasing tunneling probability. Under reverse bias, in stark contrast, electrons must traverse the full barrier structure and conduction follows conventional Schottky emission over the metal-insulator interface. This fundamental asymmetry in transport mechanisms—efficient multi-pathway conduction forward versus suppressed thermionic emission reverse—creates the extreme current rectification and ultra-high responsivity observed. The nitrogen traps are positioned within the bandgap at energies that facilitate forward transport while having minimal effect on reverse conduction, maximizing the directional preference of current flow.

The demonstrated performance advances illustrated by the above presented embodiments have immediate implications for multiple high-impact applications. For terahertz detection and spectroscopy, the combination of 1200 A/W responsivity with resistance in the 10⁶-10⁷Ω range enables unprecedented sensitivity and bandwidth. The low resistance translates to reduced RC time constants, supporting operation at frequencies into the terahertz regime—making them effective for next-generation wireless communications, security screening, and non-destructive testing. For optical rectenna energy harvesting systems, the ultra-high responsivity directly translates to improved power conversion efficiency from ambient electromagnetic radiation. The devices can capture and rectify infrared and visible light with efficiency that far exceeds previous solid-state approaches, potentially enabling practical wireless power transmission and ubiquitous energy harvesting from artificial lighting. The ability to achieve these metrics without the fabrication complexity, cost, or thermal sensitivity of semiconductor heterostructures makes these MIM diodes attractive for large-area applications and flexible electronics. Furthermore, the established design principles—combining resistance-reducing hydrogen doping with responsivity-enhancing nitrogen doping in carefully selected bilayer structures—provide a clear roadmap for future optimization and adaptation to specific frequency ranges or power levels.

The previously described MIM diode embodiments demonstrates that synergistic defect engineering and heterojunction design can overcome the fundamental performance limitations that have constrained tunnel diode technology for decades. The H—TiO₂/N—TiO₂ bilayer architecture achieves a record-breaking responsivity of 1200 A/W—more than 60 times the Schottky limit—while maintaining device resistance at practical levels for high-frequency operation. This validates the approach of combining hydrogen doping for resistance reduction with nitrogen doping for responsivity enhancement, creating asymmetric conduction mechanisms that fundamentally outperform symmetric structures. The comprehensive characterization across multiple material combinations and thicknesses establishes clear structure-property relationships and design guidelines for future development. These ultra-high responsivity, low-resistance MIM diodes represent a significant advance toward practical terahertz electronics and efficient ambient energy harvesting systems, with performance metrics that enable applications previously considered impractical for solid-state tunnel diodes.

The same previously described fabrication processes can be used to fabricate the aforementioned dual insulating layers, but instead of using hydrogen, nitrogen is used instead.

In the preceding description, for purposes of explanation, numerous details are set forth in order to provide a thorough understanding of the embodiments. However, it will be apparent to one skilled in the art that these specific details are not required. In other instances, well-known electrical structures and circuits are shown in block diagram form in order not to obscure the understanding. For example, specific details are not provided as to whether the embodiments described herein are implemented as a software routine, hardware circuit, firmware, or a combination thereof.

Embodiments of the disclosure can be represented as a computer program product stored in a machine-readable medium (also referred to as a computer-readable medium, a processor-readable medium, or a computer usable medium having a computer-readable program code embodied therein). The machine-readable medium can be any suitable tangible, non-transitory medium, including magnetic, optical, or electrical storage medium including a diskette, compact disk read only memory (CD-ROM), memory device (volatile or non-volatile), or similar storage mechanism. The machine-readable medium can contain various sets of instructions, code sequences, configuration information, or other data, which, when executed, cause a processor to perform steps in a method according to an embodiment of the disclosure. Those of ordinary skill in the art will appreciate that other instructions and operations necessary to implement the described implementations can also be stored on the machine-readable medium. The instructions stored on the machine-readable medium can be executed by a processor or other suitable processing device, and can interface with circuitry to perform the described tasks.

The above-described embodiments are intended to be examples only. Alterations, modifications and variations can be effected to the particular embodiments by those of skill in the art. The scope of the claims should not be limited by the particular embodiments set forth herein, but should be construed in a manner consistent with the specification as a whole.

1. A metal-insulator-metal diode, comprising:
a first metal electrode having a corresponding work function;
a second metal electrode having a corresponding work function, the first and the second metal electrode work function difference being at least 0 eV; and
at least one insulating layer doped and ion implanted to form intrinsic defects enhancing charge carrier mobility, in electrical communication with the first metal electrode and the second metal electrode to enable THz frequency operations between the first metal electrode and the second metal electrode.

2. The metal-insulator-metal diode of claim 1, wherein the first metal electrode is selected from the group consisting of titanium (Ti), platinum (Pt), nickel (Ni), niobium (Nb), aluminum (Al), chromium (Cr), gold (Au), silver (Ag), copper (Cu), and tantalum (Ta).

3. The metal-insulator-metal diode of claim 2, wherein the second metal electrode is selected from the same group, with the first and second metal electrode work function difference being at least 0-2 eV.

4. The metal-insulator-metal diode of claim 1, wherein the at least one insulating layer is selected from the group consisting of titanium dioxide (TiO₂), niobium pentoxide (Nb₂O₅), zinc oxide (ZnO), aluminum oxide (Al₂O₃), hafnium oxide (HfO₂), tantalum pentoxide (Ta₂O₅), cobalt oxide (Co₃O₄), nickel oxide (NiO), copper oxide (CuO), silicon dioxide (SiO₂), chromium oxide (Cr₂O₃), and vanadium pentoxide (V₂O₅).

5. The metal-insulator-metal diode of claim 4, wherein the at least one insulating layer is a single layer having a thickness of about 0.1-10 nm.

6. The metal-insulator-metal diode of claim 4, wherein the at least one insulating layer includes at least two layers having a total thickness of about 0.1-100 nm.

7. The metal-insulator-metal diode of claim 4, wherein the at least one insulating layer includes a first layer selected from the same group and a second layer selected from the same group.

8. The metal-insulator-metal diode of claim 4, wherein each of the at least one insulating layer is doped with nitrogen and ion implanted with hydrogen or treated with hydrogen, oxygen, nitrogen, or argon plasma to form the intrinsic defects.

9. The metal-insulator-metal diode of claim 1, wherein the first metal electrode is platinum (Pt), the second metal electrode is aluminum (Al) and the at least one insulating layer includes a primary layer of H—TiO₂ adjacent the first metal electrode.

10. The metal-insulator-metal diode of claim 9, wherein the at least one insulating layer includes a secondary nitrogen doped insulating layer between the second metal electrode and the primary layer of H—TiO₂.

11. The metal-insulator-metal diode of claim 10, wherein the secondary nitrogen doped insulating layer is N-Al₂O₃ between the second metal electrode and the primary layer of H—TiO₂.

12. The metal-insulator-metal diode of claim 10, wherein the secondary nitrogen doped insulating layer is N—TiO₂ between the second metal electrode and the primary layer of H—TiO₂.

13. The metal-insulator-metal diode of claim 1, wherein

14. A process for fabricating a metal-insulator-metal diode, comprising:
depositing a first metal electrode having a corresponding work function;
growing at least one oxide insulating film on the first metal electrode at a temperature of at least 100 degrees Celsius in the presence of a gas to form intrinsic defects enhancing charge carrier mobility, to a thickness of at least 0.1 nm; and, depositing a second metal electrode having a corresponding work function over the at least one oxide insulating film, the first and the second metal electrode work function difference being at least 0 eV and being in electrical communication with each other via the at least one oxide insulating film.

15. The process of claim 14, wherein depositing the first electrode includes any one of sputtering, vacuum evaporation, electron-beam deposition, chemical vapor deposition (CVD), and atomic layer deposition (ALD) of elements selected from the group consisting of titanium (Ti), platinum (Pt), nickel (Ni), niobium (Nb), aluminum (Al), chromium (Cr), gold (Au), silver (Ag), copper (Cu), and tantalum (Ta).

16. The process of claim 14, wherein growing the at least one oxide insulating film includes setting a voltage range of 50-1000 V and/or a temperature of 50-500 °C, under atmospheric pressure or in a vacuum environment ranging from 760 Torr to 10⁻¹² Torr.

17. The process of claim 14, wherein the at least one oxide insulating film is selected from the group consisting of titanium dioxide (TiO₂), niobium pentoxide (Nb₂O₅), zinc oxide (ZnO), aluminum oxide (Al₂O₃), hafnium oxide (HfO₂), tantalum pentoxide (Ta₂O₅), cobalt oxide (Co₃O₄), nickel oxide (NiO), copper oxide (CuO), silicon dioxide (SiO₂), chromium oxide (Cr₂O₃), and vanadium pentoxide (V₂O₅).

18. The process of claim 14, wherein growing the at least one oxide insulating film includes growing a single layer of film having a thickness of 0.1-10 nm, or multiple layers of film having a total thickness of 0.1-100 nm.

19. The process of claim 14, wherein growing the at least one oxide insulating film includes doping with nitrogen and either ion implanted with hydrogen, treated in situ or after deposition with hydrogen, oxygen, nitrogen, or argon plasma, or both, with at least three of these treatments or all of them.

20. The process of claim 14, wherein depositing the second metal electrode includes any one of sputtering, vacuum evaporation, electron-beam deposition, CVD, or ALD, of elements selected from the group consisting of titanium (Ti), platinum (Pt), nickel (Ni), niobium (Nb), aluminum (Al), chromium (Cr), gold (Au), silver (Ag), copper (Cu), and tantalum (Ta), with the work function difference between the first and second metal electrodes being at least 0.1-2 eV.
